(19) United States
(12) Patent Application Publication
(10) Pub. No.: US 2026/0362671 A1
(43) Pub. Date: Nov. 12, 2026

(54) SEMICONDUCTOR MEMORY DEVICE

(71) Applicant: Samsung Electronics Co., Ltd., Suwon-si (KR)

(72) Inventors: Sujin Kang, Suwon-si (KR); Minju Kang, Suwon-si (KR); Hyunjin Lee, Suwon-si (KR); Yong Kwan Kim, Suwon-si (KR); Hui-Jung Kim, Suwon-si (KR); Heejae Chae, Suwon-si (KR)

(73) Assignee: Samsung Electronics Co., Ltd., Suwon-si (KR)

(21) Appl. No.: 19/425,885

(22) Filed: Dec. 18, 2025

(30) Foreign Application Priority Data
May 8, 2025 (KR) 10-2025-0059805

(51) Int. Cl. H10B 12/00; H10D 1/68; H10W 20/41; H10W 80/00

(52) U.S. Cl. CPC H10B 12/315; H10B 12/05; H10B 12/482; H10D 1/716; H10W 20/435; H10B 12/50; H10W 80/312

(57) ABSTRACT

Disclosed is a semiconductor memory device comprising a lower dielectric layer, a bit line in the lower dielectric layer, a back-gate line that extends in a first direction on the lower dielectric layer and has a first lateral surface and a second lateral surface that face one another in a second direction substantially cross to the first direction, a first semiconductor pattern on the first lateral surface of the back-gate line, and a second semiconductor pattern on the second lateral surface of the back-gate line. The first semiconductor pattern and the second semiconductor pattern are adjacent to one another in a third direction substantially cross to the first direction and the second direction. The first direction, the second direction, and the third direction are substantially parallel to a top surface of the lower dielectric layer. The bit line is connected to the first semiconductor pattern and the second semiconductor pattern.

### CROSS-REFERENCE TO RELATED APPLICATIONS

This present application claims priority to and the benefit under 35 U.S. C § 119(a)-(d) of Korean Patent Application No. 10-2025-0059805, filed on May 8, 2025, in the Korean Intellectual Property Office, the entire disclosure of which is incorporated herein by reference.

### FIELD

The present disclosed concepts relate to a semiconductor memory device, and more particularly, to a semiconductor memory device including vertical channel transistors and a method of fabricating the same.

### BACKGROUND

With the trend of reduction in design rule of a semiconductor memory device, the fabrication technology is being improved to increase integration, operating speed, and yield of the semiconductor memory device. Accordingly, transistors with vertical channels have been suggested to increase their integration, resistance, current driving capability, and so forth.

### SUMMARY

Some embodiments of the present disclosed concepts provide a semiconductor memory device having improved electrical properties and increased integration.

The object of the present disclosed concepts is not limited to the mentioned above, and other objects which have not been mentioned above will be clearly understood to those skilled in the art from the following description.

According to some embodiments of the present disclosed concepts, a semiconductor memory device may comprise: a lower dielectric layer; a bit line in the lower dielectric layer; a back-gate line that extends in a first direction on the lower dielectric layer, the back-gate line having a first lateral surface and a second lateral surface that face one another in a second direction substantially cross to the first direction; a first semiconductor pattern on the first lateral surface of the back-gate line; and a second semiconductor pattern on the second lateral surface of the back-gate line. The first semiconductor pattern and the second semiconductor pattern may be adjacent to one another in a third direction substantially cross to the first direction and the second direction. The first direction, the second direction, and the third direction may be substantially parallel to a top surface of the lower dielectric layer. The bit line may be connected to the first semiconductor pattern and the second semiconductor pattern.

According to some embodiments of the present disclosed concepts, a semiconductor memory device may comprise: a lower dielectric layer; bit lines in the lower dielectric layer; back-gate lines that extend in a first direction on the lower dielectric layer; first semiconductor patterns on first lateral surfaces of the back-gate lines; and second semiconductor patterns on second lateral surfaces of the back-gate lines. Each of the bit lines may comprise: tab portions that vertically overlap the first semiconductor patterns and the second semiconductor patterns; and extension portions between the tab portions. Each of the extension portions may extend in a second direction substantially cross to the first direction.

According to some embodiments of the present disclosed concepts, a semiconductor memory device may comprise: a peripheral circuit structure comprising peripheral circuits on a substrate; and a cell structure electrically connected to the peripheral circuit structure. The cell structure may comprise: a lower dielectric layer; bit lines in the lower dielectric layer; back-gate lines that extend in a first direction on the lower dielectric layer; first gate lines on first lateral surfaces of the back-gate lines; second gate lines on second lateral surfaces of the back-gate lines; first semiconductor patterns between the back-gate lines and the first gate lines; second semiconductor patterns between the back-gate lines and the second gate lines; and data storage patterns on the first semiconductor patterns and the second semiconductor patterns. The first gate lines and the second gate lines may be spaced apart from one another in a second direction substantially cross to the first direction. Among the first semiconductor patterns and the second semiconductor patterns, first and second semiconductor patterns that are adjacent to one another in a third direction may be connected to one of the bit lines. The third direction may be substantially cross to the first direction and the second direction.

### BRIEF DESCRIPTION OF DRAWINGS

FIG. 1 illustrates a block diagram showing a semiconductor memory device according to some embodiments of the present disclosed concepts.

FIGS. 2 and 3 illustrate simplified diagrams showing a semiconductor memory device according to some embodiments of the present disclosed concepts.

FIG. 4 illustrates a plan view showing a semiconductor memory device according to some embodiments of the present disclosed concepts.

FIGS. 5A, 5B, and 5C illustrate cross-sectional views respectively taken along lines A-A′, B-B′, and C-C′ of FIG. 4, showing a semiconductor memory device according to some embodiments of the present disclosed concepts.

FIGS. 6A and 6B illustrate enlarged plan views showing an X region of FIG. 4.

FIG. 7 illustrates a plan view showing a semiconductor memory device according to some embodiments of the present disclosed concepts.

FIGS. 8A and 8B illustrate cross-sectional views respectively taken along lines A-A′ and B-B′ of FIG. 7, showing a semiconductor memory device according to some embodiments of the present disclosed concepts.

FIGS. 9A and 9B illustrate cross-sectional views respectively taken along lines A-A′ and B-B′ of FIG. 7, showing a semiconductor memory device according to some embodiments of the present disclosed concepts.

FIG. 10 illustrates a plan view showing a semiconductor memory device according to some embodiments of the present disclosed concepts.

FIGS. 11A and 11B illustrate cross-sectional views respectively taken along lines A-A′ and D-D′ of FIG. 10, showing a semiconductor memory device according to some embodiments of the present disclosed concepts.

FIGS. 12 and 13 illustrate plan views showing a semiconductor memory device according to some embodiments of the present disclosed concepts.

FIGS. 14A and 14B illustrate cross-sectional views taken along line A-A′ of FIG. 4, showing a semiconductor memory device according to some embodiments of the present disclosed concepts.

FIGS. 15A to 19B illustrate cross-sectional views showing a method of fabricating a semiconductor memory device according to some embodiments of the present disclosed concepts.

FIGS. 20A to 21B illustrate cross-sectional views showing a method of fabricating a semiconductor memory device according to some embodiments of the present disclosed concepts.

FIGS. 22A to 23B illustrate cross-sectional views showing a method of fabricating a semiconductor memory device according to some embodiments of the present disclosed concepts.

FIGS. 24A to 25B illustrate cross-sectional views showing a method of fabricating a semiconductor memory device according to some embodiments of the present disclosed concepts.

### DETAILED DESCRIPTION

The following will now describe some embodiments of the present disclosed concepts with reference to the accompanying drawings. Like reference numerals may indicate like components throughout the description.

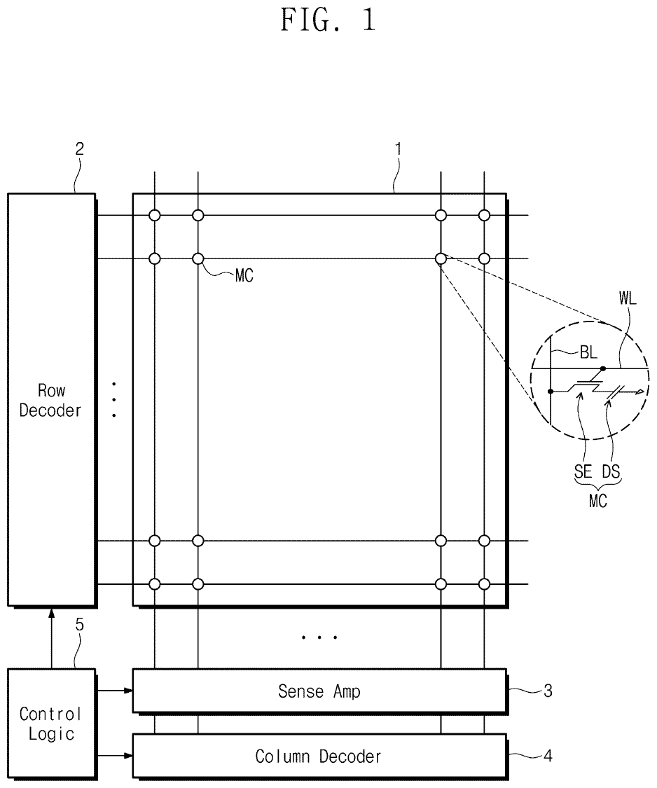

FIG. 1 illustrates a block diagram showing a semiconductor memory device according to some embodiments of the present disclosed concepts.

Referring to FIG. 1, a semiconductor memory device may include a memory cell array 1, a row decoder 2, a sense amplifier 3, a column decoder 4, and a control logic 5.

The memory cell array 1 may include a plurality of memory cells MC that are arranged two-dimensionally or three-dimensionally. Each of the plurality of memory cells MC may be connected between a word line WL and a bit line BL that intersect one another.

Each of the plurality of memory cells MC may include a selection element SE and a data storage element DS. The selection element SE and the data storage element DS may be electrically connected to one another. The selection elements SE may be correspondingly connected to the word lines WL and the bit lines BL. For example, the selection elements SE may be positioned at intersections between the word lines WL and the bit lines BL.

The selection element SE may include a field effect transistor. The data storage element DS may include a capacitor, a magnetic tunnel junction pattern, or a variable resistor. For example, a gate terminal of a transistor as the selection element SE may be connected to the word line WL, and source/drain terminals of the transistor may be connected to the bit line BL and the data storage element DS.

The low decoder 2 may decode an externally input address to select the word line WL of the memory cell array 1. The address decoded in the row decoder 2 may be provided to a row driver, and in response to control of control circuits, the row driver may provide the word line WL with a certain voltage.

In response to an address decoded from the column decoder 4, the sense amplifier 3 may detect and amplify a voltage difference of the bit line BL, and may then output the amplified voltage difference.

The column decoder 4 may provide a data delivery pathway between the sense amplifier 3 and an external device (e.g., a memory controller). The column decoder 4 may decode an address input from an external and select the bit line BL.

The control logic 5 may generate control signals that control operations to write data to the memory cell array 1 and/or to read data from the memory cell array 1.

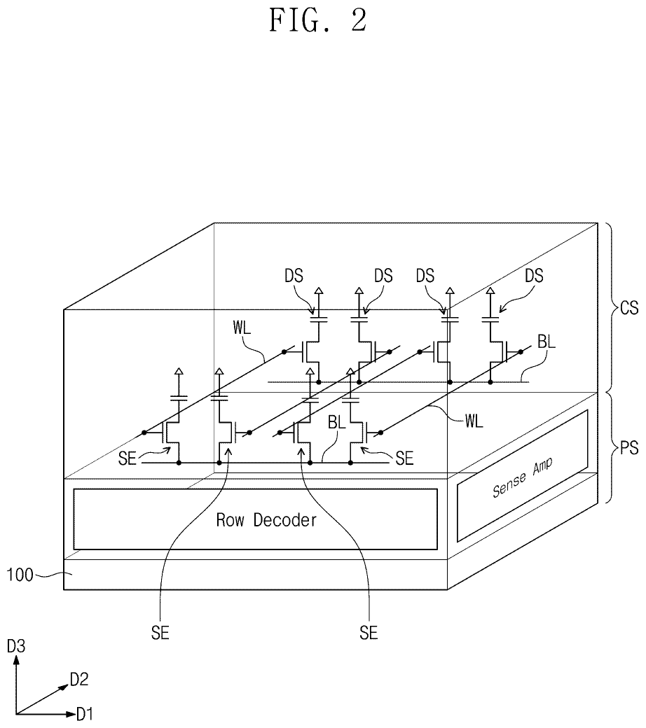

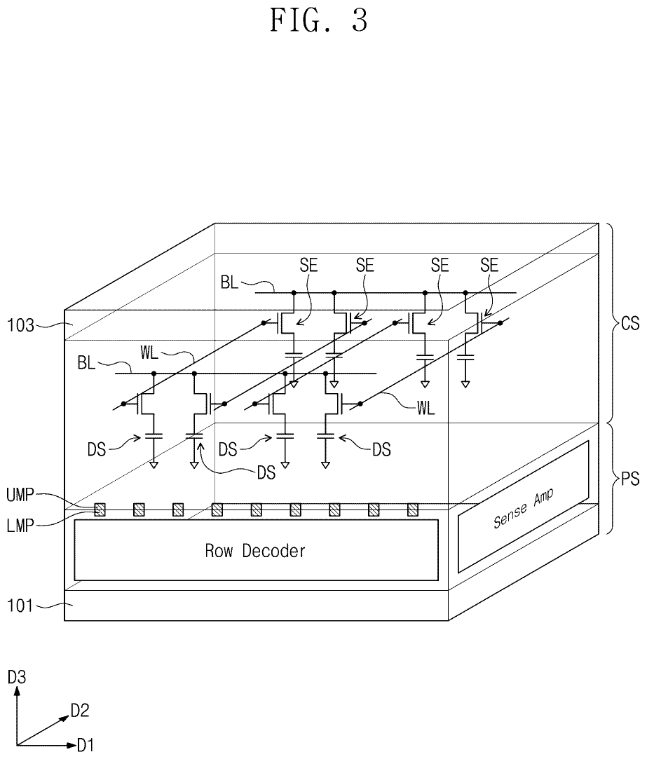

FIGS. 2 and 3 illustrate simplified diagrams showing a semiconductor memory device according to some embodiments of the present disclosed concepts.

Referring to FIGS. 2 and 3, a semiconductor memory device may include a peripheral circuit structure PS and a cell structure CS connected to the peripheral circuit structure PS.

The peripheral circuit structure PS may include core/peripheral circuits formed on a substrate 100. The core/peripheral circuits may include the row decoder 2, the column decoder 4, the sense amplifier 3, and the control logics 5 that are discussed with reference to FIG. 1.

The cell structure CS may include the memory cell array 1 including the memory cells MC that are arranged two-dimensionally or three-dimensionally discussed with reference to FIG. 1. As discussed above, each of the memory cells MC may include the selection element SE and the data storage element DS. For example, a vertical channel transistor (VCT) may be included as the selection element SE of each of the memory cells MC. The vertical channel transistor may include a channel whose lengthwise direction is perpendicular to a top surface of the substrate 100. A capacitor may be included in the data storage element DS of each of the memory cells MC.

In embodiments, the peripheral circuit structure PS may be provided on the substrate 100, and the cell structure CS may be provided on the peripheral circuit structure PS. For example, the peripheral circuit structure PS may be formed on the substrate 100, and thereafter, the cell structure CS may be formed on the peripheral circuit structure PS. Alternatively, the formation of the cell structure CS may be followed by the formation of the peripheral circuit structure PS.

In embodiments, the peripheral circuit structure PS may be provided on a first substrate 101, and the cell structure CS may be provided on a second substrate 103. The first substrate 101 and the second substrate 103 may face one another. For example, the peripheral circuit structure PS and the cell structure CS may be formed on the first substrate 101 and the second substrate 103, respectively, and then may be coupled to one another. In this case, first metal pads LMP may be provided at top of the peripheral circuit structure PS. The first metal pads LMP may be electrically connected to the core/peripheral circuits. Second metal pads UPM may be provided at bottom of the cell structure CS. The second metal pads UMP may be electrically connected to the memory cell array. The second metal pads UMP may be in direct contact with and bonded to the first metal pads LMP of the peripheral circuit structure PS.

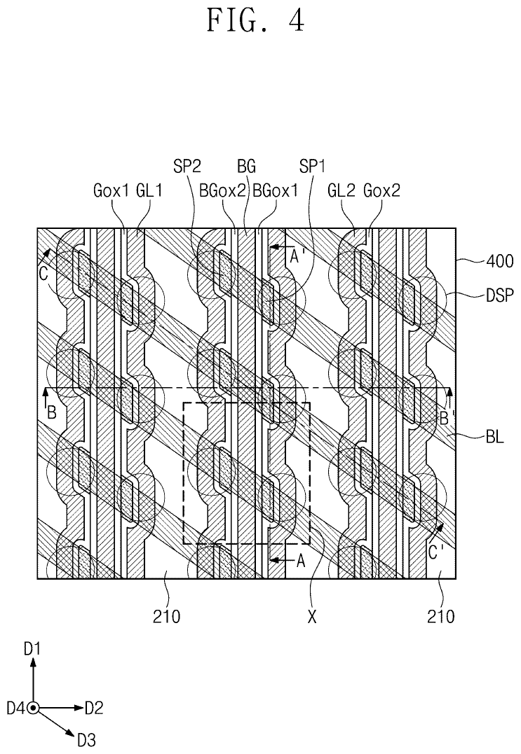

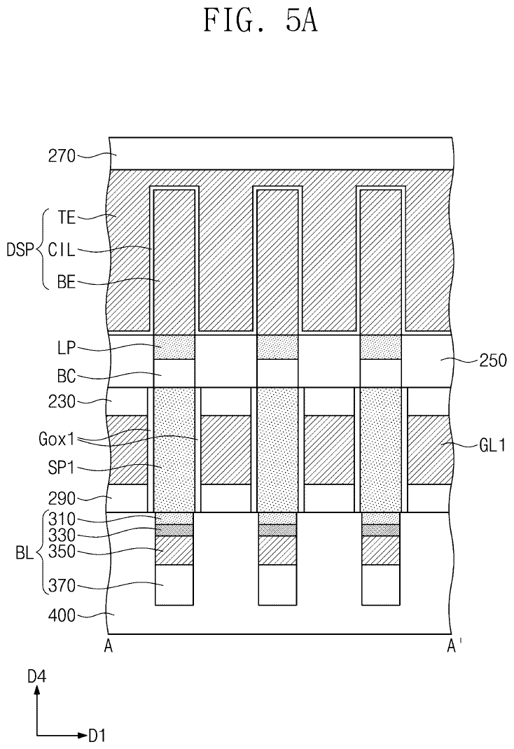

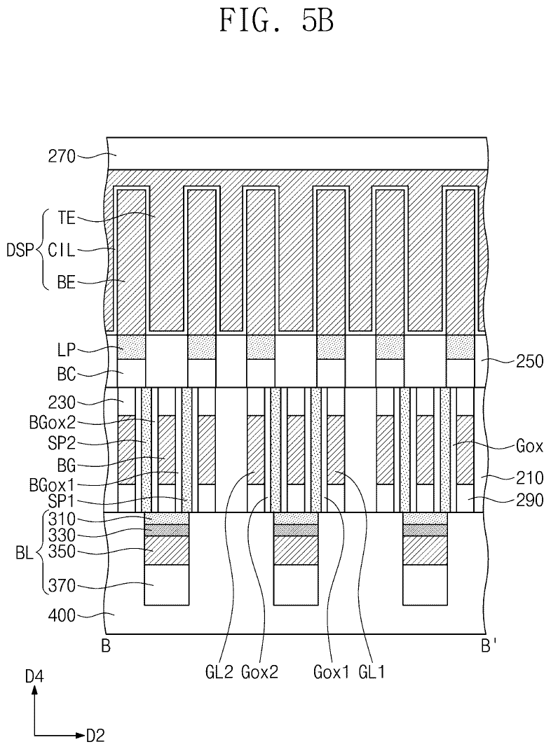

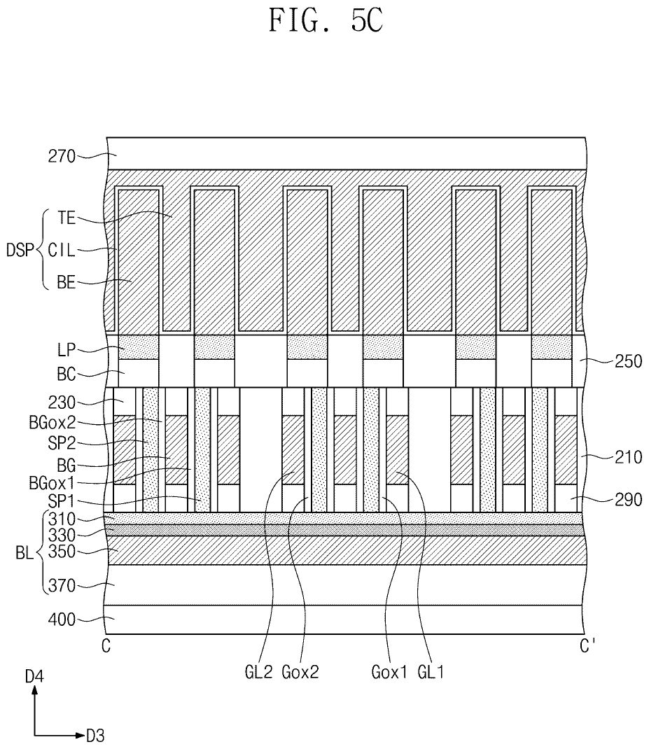

FIG. 4 illustrates a plan view showing a semiconductor memory device according to some embodiments of the present disclosed concepts. FIGS. 5A, 5B, and 5C illustrate cross-sectional views respectively taken along lines A-A′, B-B′, and C-C′ of FIG. 4, showing a semiconductor memory device according to some embodiments of the present disclosed concepts.

Referring to FIGS. 4 and 5A to 5C, there may be provided a semiconductor memory device according to the present disclosed concepts. For example, the semiconductor memory device may correspond to the cell structure CS discussed with reference to FIGS. 2 and 3.

A lower dielectric layer 400 may be provided. For example, the lower dielectric layer 400 may include a dielectric material, such as one or more of silicon oxide, silicon nitride, silicon oxynitride, and low-k dielectric. According to embodiments, the lower dielectric layer 400 may be formed of a plurality of stacked dielectric layers. For example, the lower dielectric layer 400 may have a multi-layered structure. A top surface of the lower dielectric layer 400 may be substantially parallel to a first direction D1, a second direction D2, and a third direction D3.

As used herein, the expression “substantially parallel” may refer to an orientation or alignment between two elements that is intended to be parallel, or close to parallel, relative to each other, as will be appreciated by those of skill in the art, and allows for deviations due to manufacturing tolerances, design variations, or limits of measurement. In one or more aspects, “substantially parallel” may encompass orientations that deviate within an industry-accepted tolerance, such as within ±1°, ±5°, or ±10° from 0° (or 180°).

In this description, the first direction D1, the second direction D2, and the third direction D3 may intersect one another. For example, the first direction D1 and the second direction D2 may be orthogonal to one another. The third direction D3 may be a diagonal direction with respect to the first direction D1 and the second direction D2. A fourth direction D4 may be a vertical direction with respect to the top surface of the lower dielectric layer 400. For example, the fourth direction D4 may be orthogonal to the first direction D1, the second direction D2, and the third direction D3.

The lower dielectric layer 400 may be provided with bit lines BL therein. Each of the bit lines BL may extend in the third direction D3. The bit lines BL may be spaced apart from one another in the first direction D1 and the second direction D2. When viewed in plan, each of the bit lines BL may have a linear or bar shape. A top surface of each of the bit lines BL may be coplanar with the top surface of the lower dielectric layer 400. For example, each of the bit lines BL may include a first line 310, a second line 330, a third line 350, and a capping line 370 that are stacked in the fourth direction D4. The first line 310, the second line 330, the third line 350, and the capping line 370 may vertically overlap in each of the bit lines BL. For example, the first line 310 may include impurity-doped polysilicon. The second line 330 may include titanium. The third line 350 may include tungsten. The capping line 370 may include silicon nitride.

The lower dielectric layer 400 may be provided with back-gate lines BG thereon. Each of the back-gate lines BG may extend in the first direction D1, while substantially crossing over the bit lines BL. The back-gate lines BG may be spaced apart from one another in the second direction D2. Each of the back-gate lines BG may have a width that is uniform along the second direction D2. The back-gate lines BG may adjust threshold voltages of transistors. Therefore, the semiconductor memory device may improve in electrical properties.

As used herein, the expression “substantially cross” may refer to an orientation, alignment, or intersection between two elements that is intended to be perpendicular, or close to perpendicular, relative to each other, as will be appreciated by those of skill in the art, and allows for deviations due to manufacturing tolerances, design variations, or limits of measurement. In one or more aspects, “substantially cross” may encompass orientations that deviate within an industry-accepted tolerance, such as within ±1°, ±5°, or ±10° of 90°.

The lower dielectric layer 400 may be provided thereon with first gate lines GL1 and second gate lines GL2 that substantially cross over the bit lines BL. For example, a pair of first and second gate lines GL1 and GL2 may be positioned on opposite sides of each of the back-gate lines BG. The first gate lines GL1 may be spaced apart from one another in the second direction D2, while extending in the first direction D1, and this may be true for the second gate lines GL2. When viewed in plan, the first gate lines GL1 and the second gate lines GL2 may partially surround first semiconductor patterns SP1 and second semiconductor patterns SP2, respectively, which will be discussed below.

The back-gate lines BG, the first gate lines GL1, and the second gate lines GL2 may include doped polysilicon, metal, conductive metal nitride, conductive metal silicide, conductive metal oxide, or any combination thereof. For example, the back-gate lines BG, the first gate lines GL1, and the second gate lines GL2 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof, but the present disclosed concepts are not limited thereto.

A lower buried layer 290 may be provided beneath the back-gate lines BG, the first gate lines GL1, and the second gate lines GL2. The lower buried layer 290 may be positioned between the back-gate lines BG and the lower dielectric layer 400, between the first gate lines GL1 and the lower dielectric layer 400, and between the second gate lines GL2 and the lower dielectric layer 400. Therefore, the back-gate lines BG, the first gate lines GL1, and the second gate lines GL2 may be spaced apart in the fourth direction D4 from the lower dielectric layer 400 and the bit lines BL, and may be electrically insulated from the bit lines BL. For example, the lower buried layer 290 may include a dielectric material, such as one or more of silicon oxide, silicon nitride, silicon oxynitride, and low-k dielectric.

An upper buried layer 230 may be provided on the back-gate lines BG, the first gate lines GL1, and the second gate lines GL2. The upper buried layer 230 may be positioned between the back-gate lines BG and an interlayer dielectric layer 250 which will be discussed below, between the first gate lines GL1 and the interlayer dielectric layer 250, and between the second gate lines GL2 and the interlayer dielectric layer 250. Therefore, the back-gate lines BG, the first gate lines GL1, and the second gate lines GL2 may be spaced apart in the fourth direction D4 and electrically insulated from the data storage patterns DSP which will be discussed below. For example, the upper buried layer 230 and the lower buried layer 290 may include the same dielectric material.

The lower dielectric layer 400 may be provided thereon with first semiconductor patterns SP1 that are two-dimensionally arranged. The first semiconductor patterns SP1 may be positioned between the back-gate lines BG and the first gate lines GL1. The first semiconductor patterns SP1, between the back-gate line BG and its neighboring first gate line GL1, may be spaced apart from one another in the first direction D1. Each of the first semiconductor patterns SP1 may extend in the fourth direction D4 from the top surface of the lower dielectric layer 400. A vertical length in the fourth direction D4 of the first semiconductor pattern SP1 may be greater than a vertical length in the fourth direction D4 of each of the back-gate line BG, the first gate line GL1, and the second gate line GL2.

The lower dielectric layer 400 may be provided thereon with second semiconductor patterns SP2 that are two-dimensionally arranged and spaced apart from the first semiconductor patterns SP1. The second semiconductor patterns SP2 may be positioned between the back-gate lines BG and the second gate lines GL2. The second semiconductor patterns SP2, between the back-gate line BG2 and its neighboring second gate line GL2, may be spaced apart from one another in the first direction D1. The second semiconductor patterns SP2 may extend in the fourth direction D4 from the top surface of the lower dielectric layer 400, and may have substantially the same vertical length as that of the first semiconductor patterns SP1.

As used herein, the expression “substantially the same” may refer to having the same measurement value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances

Among the first semiconductor patterns SP1 and the second semiconductor patterns SP2, a pair of neighboring first and second semiconductor patterns SP1 and SP2 may be spaced apart in the third direction D3 from one another so as to substantially cross the back-gate line BG. For example, a pair of first and second semiconductor patterns SP1 and SP2 positioned on opposite sides of each of the back-gate lines BG may be adjacent to one another in the third direction D3. Therefore, the first semiconductor pattern SP1 and the second semiconductor pattern SP2 may not be aligned with one another in the second direction D2. When viewed in plan, the first semiconductor patterns SP1 and the second semiconductor patterns SP2 may be arranged in a zigzag fashion.

The first semiconductor patterns SP1 and the second semiconductor patterns SP2 may be positioned on and connected to the bit lines BL. A pair of first and second semiconductor patterns SP1 and SP2 adjacent to one another in the third direction D3 may be connected to one of the bit lines BL. For example, a pair of first and second semiconductor patterns SP1 and SP2 adjacent to one another in the third direction D3 may be connected to the same bit line BL. In such a case, the first semiconductor patterns SP1 and the second semiconductor patterns SP2 positioned on the same bit line BL may be aligned along the third direction D3.

The first and second semiconductor patterns SP1 and SP2 may include silicon. For example, the first and second semiconductor patterns SP1 and SP2 may include impurity-doped monocrystalline silicon or impurity-undoped monocrystalline silicon. Each of the first and second semiconductor patterns SP1 and SP2 that extend in the fourth direction D4 may serve as a channel of a transistor in the semiconductor memory device. For example, the semiconductor memory device may include a vertical channel transistor having a channel that extends in the fourth direction D4. Consequently, the semiconductor memory device may increase in integration.

Each of the back-gate lines BG may be provided with first and second back-gate dielectric layers BGox1 and BGox2 on opposite sides thereof. The first and second back-gate dielectric layers BGox1 and BGox2 may extend in the first direction D1 along the back-gate lines BG. For example, the first back-gate dielectric layers BGox1 may be positioned between and in contact with the back-gate lines BG and the first semiconductor patterns SP1. The second back-gate dielectric layers BGox2 may be positioned between and in contact with the back-gate lines BG and the second semiconductor patterns SP2.

First gate dielectric layers Gox1 may be provided between the first gate lines GL1 and the first semiconductor patterns SP1. Second gate dielectric layers Gox2 may be provided between the second gate lines GL2 and the second semiconductor patterns SP2. The first gate dielectric layers Gox1 may be in partial contact with the first semiconductor patterns SP1. The first gate dielectric layers Gox1 may be in contact with the first back-gate dielectric layers BGox1 on a region where the first gate dielectric layers Gox1 are not in contact with the first semiconductor patterns SP1. The second gate dielectric layers Gox2 may be in partial contact with the second semiconductor patterns SP2. The second gate dielectric layers Gox2 may be in contact with the second back-gate dielectric layers BGox2 on a region where the second gate dielectric layers Gox2 are not in contact with the second semiconductor patterns SP2.

The first gate dielectric layers Gox1 and the second gate dielectric layers Gox2 may extend in the first direction D1 along the first gate lines GL1 and the second gate lines GL2, respectively. When viewed in plan, the first gate dielectric layers Gox1 may partially surround the first semiconductor patterns SP1, and the second gate dielectric layers Gox2 may partially surround the second semiconductor patterns SP2. For example, the first gate dielectric layers Gox1 and the second gate dielectric layers Gox2 may have similar profiles to those of the first gate lines GL1 and the second gate lines GL2, respectively.

The back-gate dielectric layers BGox, the first gate dielectric layers Gox1, and the second gate dielectric layers Gox2 may be formed of silicon oxide, silicon oxynitride, silicon nitride, high-k dielectric, or any combination thereof. In this description, the high-k dielectric may be a material whose dielectric constant is greater than that of silicon oxide. For example, the high-k dielectric may include HfO₂, HfSiO, HfSiON, HfTaO, HfTiO, HfZrO, ZrO₂, Al₂O₃, or any combination thereof.

Each of capping dielectric patterns 210 may be provided between a pair of back-gate lines BG. For example, between a pair of back-gate lines BG, each of the capping dielectric patterns 210 may be positioned between the first gate line GL1 and the second gate line GL2 that are adjacent to one another in the second direction D2. Each of the capping dielectric patterns 210 may extend in the first direction D1 between the first gate line GL1 and the second gate line GL2. The capping dielectric patterns 210 may be in contact with the top surface of the lower dielectric layer 400 and a bottom surface of an interlayer dielectric layer 250 which will be discussed below. For example, the capping dielectric patterns 210 may include a dielectric material, such as one or more of silicon oxide, silicon nitride, silicon oxynitride, and any combination thereof.

An interlayer dielectric layer 250 may be provided on the first semiconductor patterns SP1, the second semiconductor patterns SP2, and the capping dielectric patterns 210. The interlayer dielectric layer 250 may cover the first semiconductor patterns SP1, the second semiconductor patterns SP2, the capping dielectric patterns 210, and the upper buried layer 230 with an uniform thickness, and may come into contact with the first semiconductor patterns SP1, the second semiconductor patterns SP2, the capping dielectric patterns 210, and the upper buried layer 230. According to embodiments, the interlayer dielectric layer 250 may be formed of multiple layers including a plurality of dielectric layers.

The interlayer dielectric layer 250 may be provided therein with lower contacts BC and landing pads LP in contact with the lower contacts BC. The lower contacts BC and the landing pads LP may be correspondingly sequentially positioned on the first semiconductor patterns SP1 and the second semiconductor patterns SP2. The lower contact BC and the landing pad LP in contact with one another may vertically overlap. For example, the lower contacts BC may be correspondingly in contact with the first semiconductor patterns SP1 and the second semiconductor patterns SP2, and the landing pads LP may be correspondingly in contact with bottom electrodes BE of data storage patterns DSP which will be discussed below. Thus, the first semiconductor patterns SP1 and the second semiconductor patterns SP2 may be electrically connected to the data storage patterns DSP through the lower contacts BC and the landing pads LP. For example, the lower contacts BC and the landing pads LP may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof.

Data storage patterns DSP may be provided on the interlayer dielectric layer 250. The data storage patterns DSP may be two-dimensionally arranged. The data storage patterns DSP may correspondingly overlap the first semiconductor patterns SP1 and the second semiconductor patterns SP2. For example, the data storage patterns DSP may correspondingly vertically overlap the first semiconductor patterns SP1 and the second semiconductor patterns SP2. When viewed in plan, as the first semiconductor patterns SP1 and the second semiconductor patterns SP2 are arranged in a zigzag fashion, the data storage patterns DSP may be arranged in a honeycomb fashion. Therefore, there may be a reduction in the number of the data storage patterns DSP adjacent to one of other data storage patterns DSP, which may reduce electrical interference between the data storage patterns DSP. Accordingly, the semiconductor memory device may improve in electrical properties.

The data storage patterns DSP may include bottom electrodes BE, a top electrode TE, and a capacitor dielectric layer CIL between the bottom electrodes BE and the top electrode TE. The bottom electrodes BE may extend in the fourth direction D4 on corresponding landing pads LP. The capacitor dielectric layer CIL may have an uniform thickness that covers the lower electrodes BE. The capacitor dielectric layer CIL may extend from on the bottom electrodes BE onto the interlayer dielectric layer 250. The top electrode TE may cover the bottom electrodes BE. According to embodiments, the top electrode TE may be provided in plural. In this case, a plurality of top electrodes TE may be positioned on corresponding bottom electrodes BE.

According to embodiments, the data storage patterns DSP may include a magnetic tunnel junction pattern. In this case, the semiconductor memory device according to the present disclosed concepts may be a magnetic random access memory (MRAM). According to embodiments, the data storage patterns DSP may include a phase change material or a variable resistance material. In this case, the semiconductor memory device according to the present disclosed concepts may be a phase-change random access memory (PRAM) or a resistive random access memory (ReRAM). This is, however, merely exemplary, and the present disclosed concepts are not limited thereto. The data storage patterns DSP may include various structures and/or materials capable of storing data.

An upper dielectric layer 270 may be provided on the data storage patterns DSP. The upper dielectric layer 270 may cover the top electrode TE of the data storage patterns DSP. The upper dielectric layer 270 may include the same dielectric material as that of the lower dielectric layer 400, but the present disclosed concepts are not limited thereto.

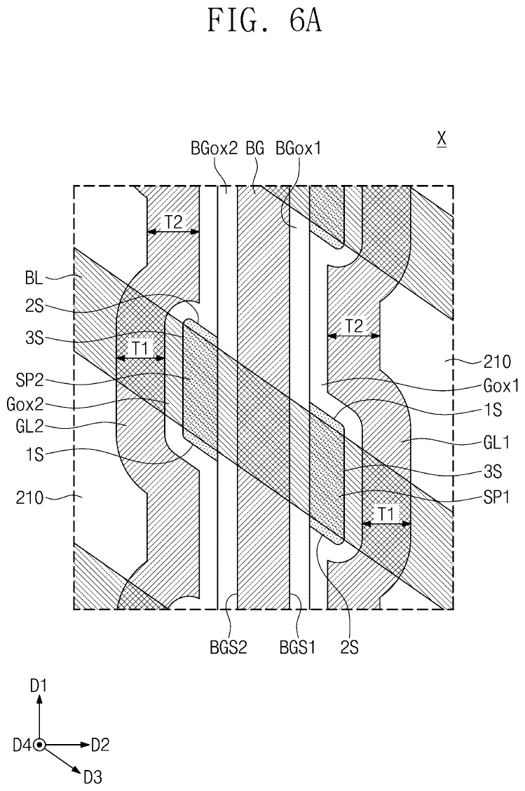

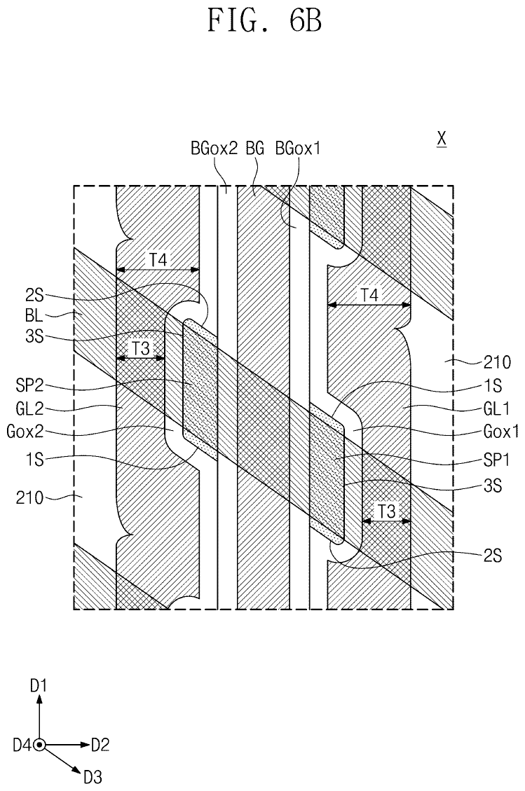

FIGS. 6A and 6B illustrate enlarged plan views showing an X region of FIG. 4.

For convenience of explanation, omission will be made to avoid descriptions of the same features as those discussed with reference to FIGS. 4 and 5A to 5C, and differences will be described in detail below.

Referring to FIGS. 6A and 6B, the back-gate line BG may have a first lateral surface BGS1 and a second lateral surface BGS2 that extend in the first direction D1 and face one another in the second direction D2. The first back-gate dielectric layer BGox1 may be positioned on the first lateral surface BGS1 of the back-gate line BG, and may extend in the first direction D1 along the back-gate line BG. The second back-gate dielectric layer BGox2 may be positioned on the second lateral surface BGS2 of the back-gate line BG, and may extend in the first direction D1 along the back-gate line BG. For example, the first back-gate dielectric layer BGox1 may be in contact with the first lateral surface BGS1 of the back-gate line BG, and the second back-gate dielectric layer BGox2 may be in contact with the second lateral surface BGS2 of the back-gate line BG.

The first semiconductor pattern SP1 on the first lateral surface BGS1 of the back-gate line BG may be in contact with the first back-gate dielectric layer BGox1. The second semiconductor pattern SP2 on the second lateral surface BGS2 of the back-gate line BG may be in contact with the second back-gate dielectric layer BGox2. The first semiconductor pattern SP1 and the second semiconductor pattern SP2 may be spaced apart from one another in the first direction D1 and the second direction D2. For example, the first semiconductor pattern SP1 and the second semiconductor pattern SP2 may be offset from one another in the first direction D1. In such a case, the first semiconductor pattern SP1 and the second semiconductor pattern SP2 may be adjacent to one another in the third direction D3 substantially crossing the back-gate line BG.

Each of the first and second semiconductor patterns SP1 and SP2 may have first, second, and third surfaces 1S, 2S, and 3S. In each of the first and second semiconductor patterns SP1 and SP2, the first surface 1S and the second surface 2S may be substantially parallel to one another, and the third surface 3S may be positioned between the first surface 1S and the second surface 2S. The third surface 3S of each of the first and second semiconductor patterns SP1 and SP2 may be spaced apart from the first back-gate dielectric layer BGox1 and the second back-gate dielectric layer BGox2. For example, in each of the first and second semiconductor patterns SP1 and SP2, the first surface 1S and the second surface 2S may be substantially parallel to the third direction D3, and the third surface 3S may be substantially parallel to the first direction D1. When viewed in plan, each of the first and second semiconductor patterns SP1 and SP2 may have a tetragonal shape. The present disclosed concepts, however, are not limited thereto, and each of the first and second semiconductor patterns SP1 and SP2 may have one or more of a triangular planar shape, a hemicyclic planar shape, and a polygonal planar shape.

The bit line BL may be positioned to extend in the third direction D3 beneath the first semiconductor pattern SP1 and the second semiconductor pattern SP2. A pair of first and second semiconductor patterns SP1 and SP2 that are adjacent to one another in the third direction D3 may vertically overlap one bit line BL. For example, a pair of first and second semiconductor patterns SP1 and SP2 that are adjacent to one another in the third direction D3 may be connected to and share one bit line BL.

The first lateral surface BGS1 of the back-gate line BG may be sequentially provided thereon with the first gate dielectric layer Gox1 and the first gate line GL1 that are in contact with one another. The first gate dielectric layer Gox 1 may be closer than the first gate line GL1 to the back-gate line BG. The first gate dielectric layer Gox1 may extend onto the first back-gate dielectric layer BGox1 from on the first, second, and third surfaces 1S, 2S, and 3S of the first semiconductor pattern SP1. For example, the first gate dielectric layer Gox1 may be in contact with the first back-gate dielectric layer BGox1 and the first to third surfaces 1S to 3S of the first semiconductor pattern SP1. In such a case, the first gate dielectric layer Gox1 may be in partial contact with each of the first semiconductor pattern SP1 and the first back-gate dielectric layer BGox1.

The second lateral surface BGS2 of the back-gate line BG may be sequentially provided thereon with the second gate dielectric layer Gox2 and the second gate line GL2 that are in contact with one another. The second gate dielectric layer Gox2 may be closer than the second gate line GL2 to the back-gate line BG. The second gate dielectric layer Gox2 may extend onto the second back-gate dielectric layer BGox2 from on the first, second, and third surfaces 1S, 2S, and 3S of the second semiconductor pattern SP2. For example, the second gate dielectric layer Gox2 may be in contact with the second back-gate dielectric layer BGox2 and the first to third surfaces 1S to 3S of the second semiconductor pattern SP2. In such a case, the second gate dielectric layer Gox2 may be in partial contact with each of the second semiconductor pattern SP2 and the second back-gate dielectric layer BGox2.

Likewise the first gate dielectric layer Gox1, the first gate line GL1 may extend onto the first back-gate dielectric layer BGox1 from on the first, second, and third surfaces 1S, 2S, and 3S of the first semiconductor pattern SP1. Likewise the second gate dielectric layer Gox2, the second gate line GL2 may extend onto the second back-gate dielectric layer BGox2 from on the first, second, and third surfaces 1S, 2S, and 3S of the second semiconductor pattern SP2. For example, the first gate line GL1 may be positioned on the first, second, and third surfaces 1S, 2S, and 3S of the first semiconductor pattern SP1, and the second gate line GL2 may be positioned on the first, second, and third surfaces 1S, 2S, and 3S of the second semiconductor pattern SP2. Therefore, the first gate line GL1 and the second gate line GL2 may respectively control the first semiconductor pattern SP1 and the second semiconductor pattern SP2, which serve as channels of transistors, through the first, second, and third surfaces 1S, 2S, and 3S. Consequently, the semiconductor memory device may improve in gate controllability.

According to embodiments, each of the first and second gate lines GL1 and GL2 may be provided to have a relatively small thickness. In this case, each of the first and second gate lines GL1 and GL2 may have an uniform thickness. For example, each of the first gate line GL1 and the second gate line GL2 may have a first thickness T1 in the second direction D2 on the third surface 3S of the first semiconductor pattern SP1 and the second semiconductor pattern SP2, respectively. Each of the first and second gate lines GL1 and GL2 may have a second thickness T2 in the second direction D2 on its portion adjacent to the back-gate line BG. For example, the first thickness T1 and the second thickness T2 may be substantially the same.

According to embodiments, each of the first and second gate lines GL1 and GL2 may be provided to have a relatively large thickness. In this case, each of the first and second gate lines GL1 and GL2 may have a non-uniform thickness. For example, each of the first gate line GL1 and the second gate line GL2 may have a third thickness T3 in the second direction D2 on the third surface 3S of the first semiconductor pattern SP1 and the second semiconductor pattern SP2, respectively. Each of the first and second gate lines GL1 and GL2 may have a fourth thickness T4 in the second direction D2 on its portion adjacent to the back-gate line BG. For example, the third thickness T3 may be less than the fourth thickness T4. In such a case, a thickness in the second direction D2 of each of the first and second gate lines GL1 and GL2 may be changed along the first direction D1.

The capping dielectric patterns 210 may be positioned on lateral surfaces of the first and second gate lines GL1 and GL2. The first gate line GL1 and the second gate line GL2 may separate the capping dielectric patterns 210 from the first semiconductor pattern SP1, the second semiconductor pattern SP2, and the back-gate line BG.

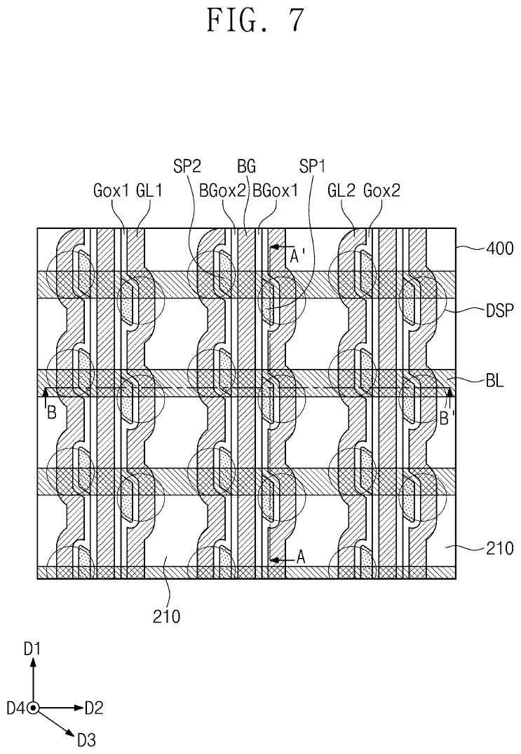

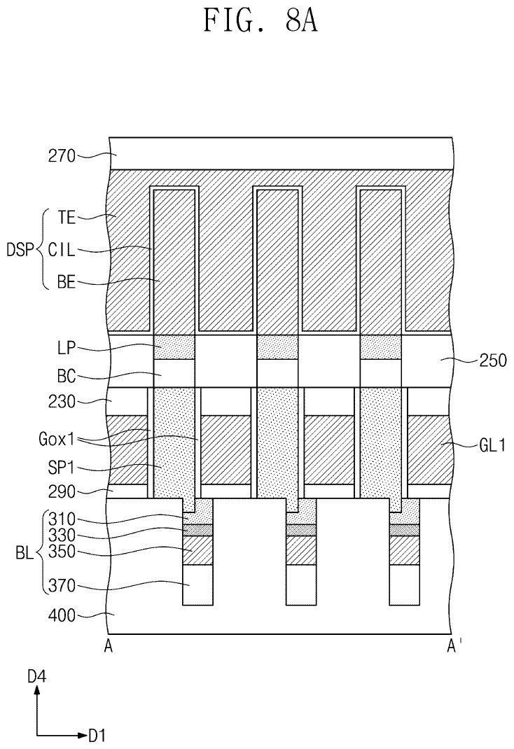

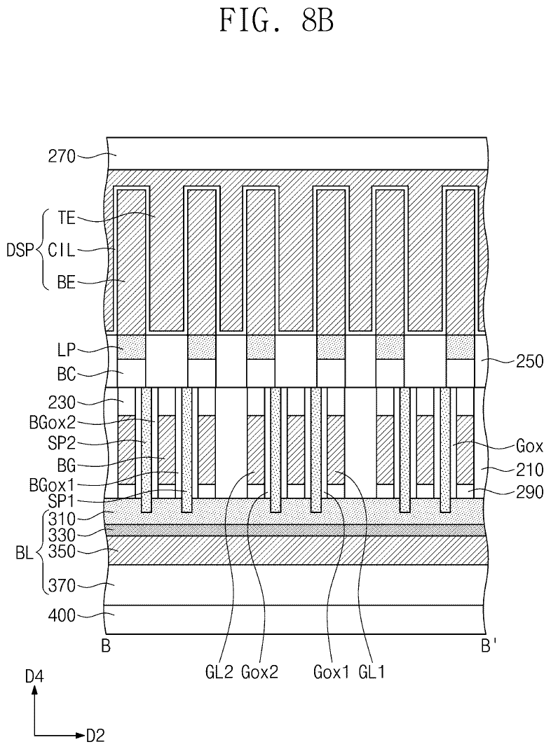

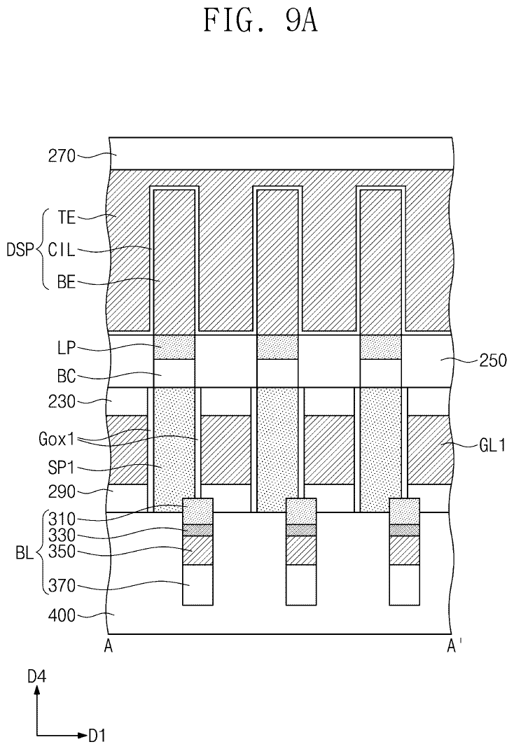

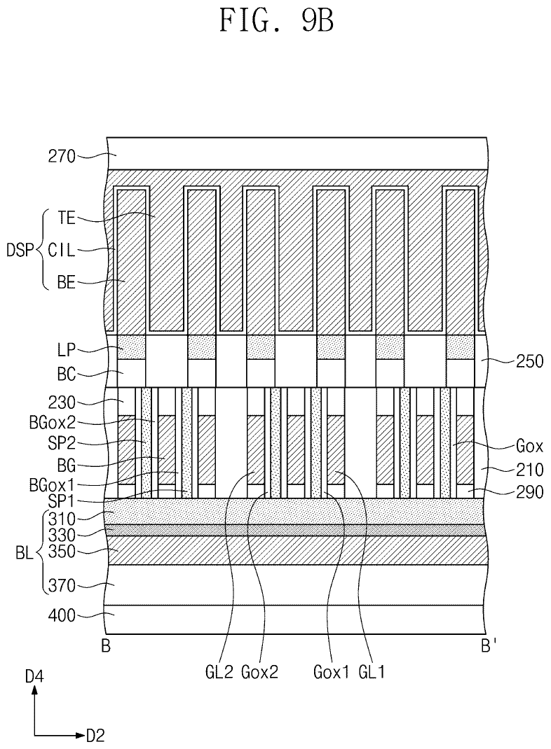

FIG. 7 illustrates a plan view showing a semiconductor memory device according to some embodiments of the present disclosed concepts. FIGS. 8A and 8B illustrate cross-sectional views respectively taken along lines A-A′ and B-B′ of FIG. 7, showing a semiconductor memory device according to some embodiments of the present disclosed concepts. FIGS. 9A and 9B illustrate cross-sectional views respectively taken along lines A-A′ and B-B′ of FIG. 7, showing a semiconductor memory device according to some embodiments of the present disclosed concepts.

For convenience of explanation, omission will be made to avoid descriptions of the same features as those discussed with reference to FIGS. 4 and 5A to 5C, and differences will be described in detail below.

Referring to FIGS. 7, 8A, and 8B, the bit lines BL in the lower dielectric layer 400 may extend in the second direction D2 and may be spaced apart from one another in the first direction D1. When viewed in plan, the bit lines BL may correspondingly partially overlap the first semiconductor patterns SP1 and the second semiconductor patterns SP2. For example, the first semiconductor patterns SP1 and the second semiconductor patterns SP2 may be offset in and counter to the first direction D1 so as to substantially cross corresponding bit lines BL.

The first semiconductor patterns SP1 and the second semiconductor patterns SP2 may further extend into the bit lines BL For example, the first semiconductor patterns SP1 and the second semiconductor patterns SP2 may have their shapes that protrude from the lower buried layer 290 and the capping dielectric patterns 210. The first line 310 of each of the bit lines BL may partially cover a protruding portion of each of the first and second semiconductor patterns SP1 and SP2. For example, the protruding portion of each of the first and second semiconductor patterns SP1 and SP2 may extend into the first lines 310 of the bit lines BL. Thus, the first semiconductor patterns SP1 and the second semiconductor patterns SP2 may three-dimensionally contact corresponding bit lines BL, which may cause an increase in contact area between the bit line BL and each of the first and second semiconductor patterns SP1 and SP2. Accordingly, the semiconductor memory device may improve in electrical properties.

Referring to FIGS. 7, 9A, and 9B, the bit lines BL in the lower dielectric layer 400 may extend in the second direction D2 and may be spaced apart from one another in the first direction D1. When viewed in plan, the bit lines BL may correspondingly partially overlap the first semiconductor patterns SP1 and the second semiconductor patterns SP2. For example, the first semiconductor patterns SP1 and the second semiconductor patterns SP2 may be offset in and counter to the first direction D1 so as to substantially cross corresponding bit lines BL.

The bit lines BL may correspondingly further extend into the first semiconductor patterns SP1 and the second semiconductor patterns SP2. For example, the first line 310 of each of the bit lines BL may have a shape that protrudes from the lower dielectric layer 400. The first semiconductor patterns SP1, the second semiconductor patterns SP2, and the lower buried layer 290 may correspondingly cover a protruding portion of the first lines 310 of the bit lines BL. For example, the protruding portion of the first lines 310 of the bit lines BL may correspondingly extend into the first semiconductor patterns SP1 and the second semiconductor patterns SP2. Thus, the bit lines BL may correspondingly three-dimensionally contact the first semiconductor patterns SP1 and the second semiconductor patterns SP2, which may cause an increase in contact area between the bit line BL and each of the first and second semiconductor patterns SP1 and SP2. Accordingly, the semiconductor memory device may improve in electrical properties.

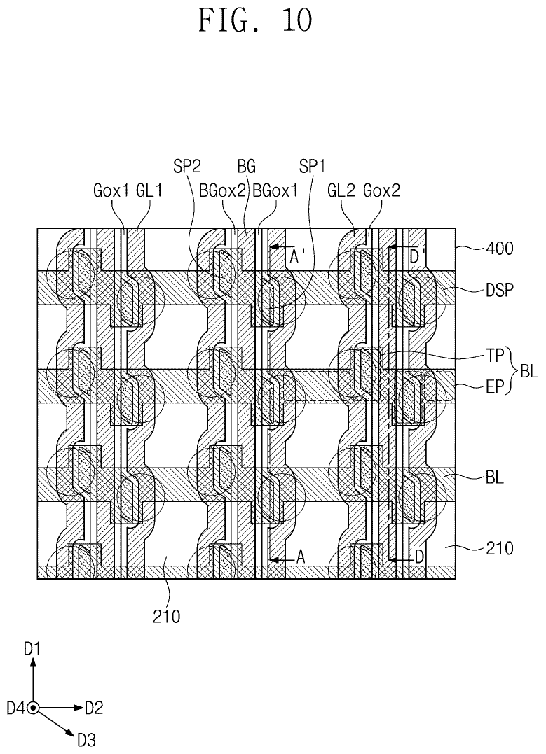

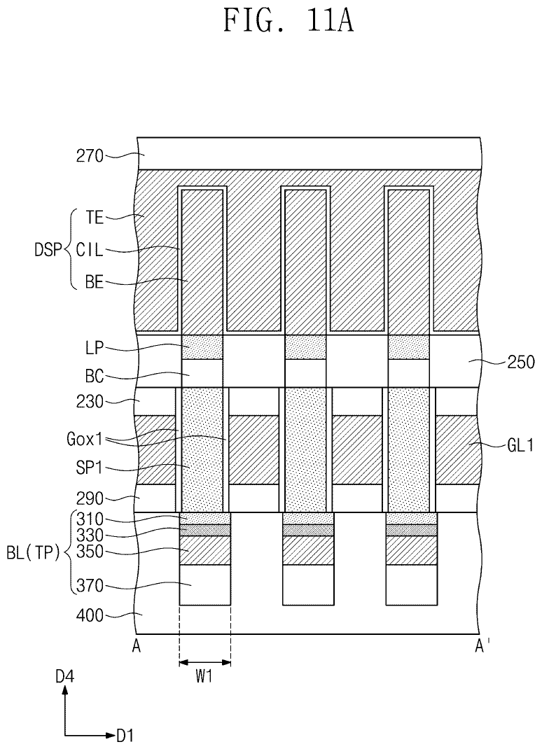

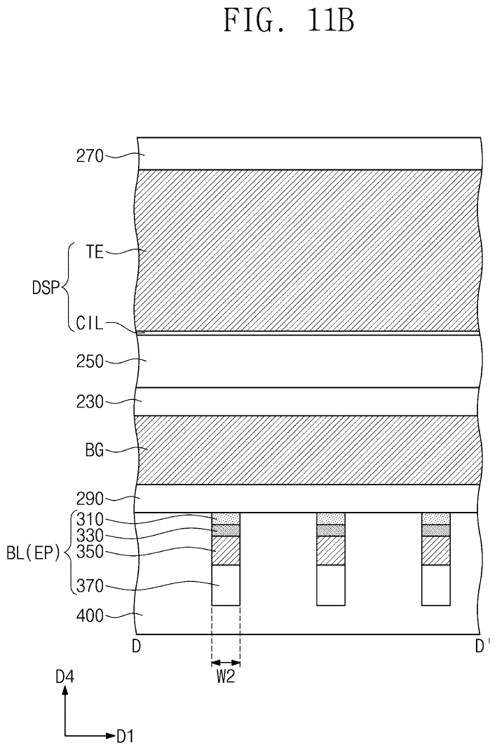

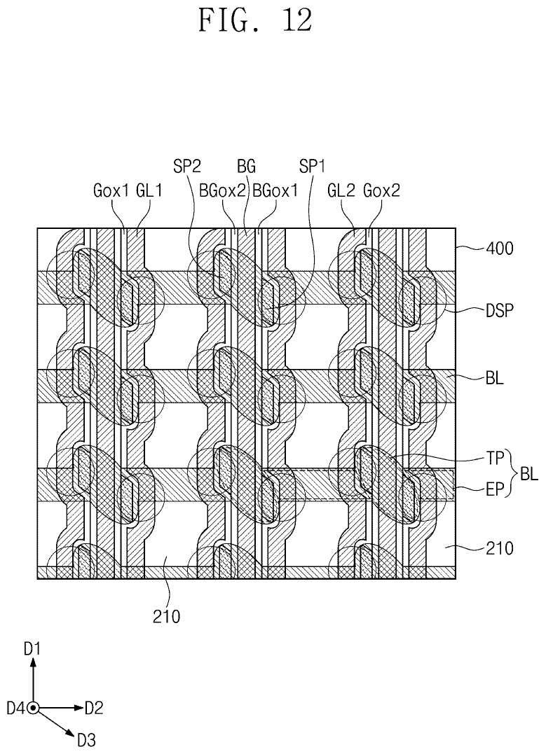

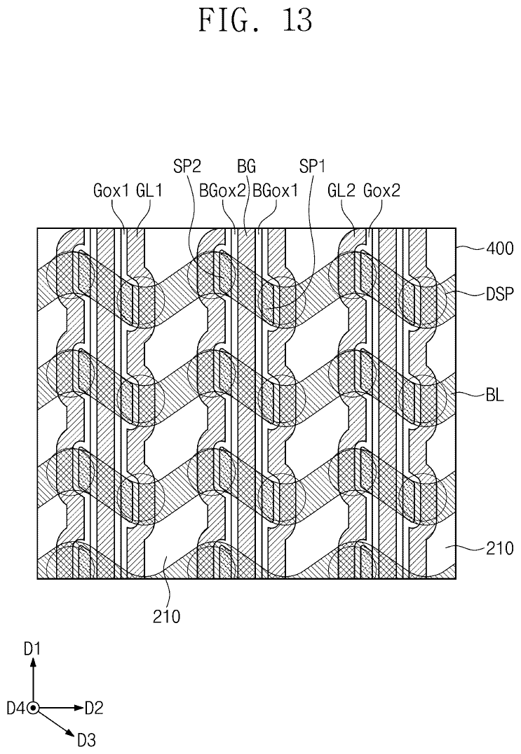

FIG. 10 illustrates a plan view showing a semiconductor memory device according to some embodiments of the present disclosed concepts. FIGS. 11A and 11B illustrate cross-sectional views respectively taken along lines A-A′ and D-D′ of FIG. 10, showing a semiconductor memory device according to some embodiments of the present disclosed concepts. FIGS. 12 and 13 illustrate plan views showing a semiconductor memory device according to some embodiments of the present disclosed concepts.

For convenience of explanation, omission will be made to avoid descriptions of the same features as those discussed with reference to FIGS. 4 and 5A to 5C, and differences will be described in detail below.

Referring to FIGS. 10, 11A, and 11B, the bit lines BL in the lower dielectric layers 400 may include tab portions TP and extension portions EP between the tab portions TP. The tab portions TP may correspondingly vertically overlap the first semiconductor patterns SP1 and the second semiconductor patterns SP2. Each of the extension portions EP may be positioned between the tab portions TP to permit connection between the tab portions TP. When viewed in plan, each of the tab portions TP may have a tetragonal shape, but the present disclosed concepts are not limited thereto. When viewed in plan, each of the extension portions EP may have a linear or bar shape that extends in the second direction D2.

The tab portions TP of each of the bit lines BL may be two-dimensionally arranged. For example, the tab portions TP of each of the bit lines BL may be spaced apart from one another in the second direction D2 and offset from one another in the first direction D1. In such a case, the tab portions TP of each of the bit lines BL may not be aligned with one another in the first direction D1. When viewed in plan, the tab portions TP of the bit lines BL may be arranged in a zigzag fashion.

Each of the tab portions TP may have a first width W1 in the first direction D1. For example, the first width W1 of each of the tab portions TP may be greater than a horizontal width of each of the first and second semiconductor patterns SP1 and SP2. There may be an increase in vertical overlapping area between the tab portion TP and each of the first and second semiconductor patterns SP1 and SP2. Therefore, there may be an increase in contact area between the bit line BL and each of the first and second semiconductor patterns SP1 and SP2 that are in contact with the bit line BL. Accordingly, the semiconductor memory device may improve in electrical properties.

Each of the extension portions EP may have a second width W2 in the first direction D1. The second width W2 may be less than the first width W1, and thus a width in the first direction D1 of each of the bit lines BL may be changed along the second direction D2. For example, there may be an increase in interval between neighboring bit lines BL except their portions that vertically overlap the first semiconductor patterns SP1 and the second semiconductor patterns SP2. Thus, it may be possible to minimize electrical interference between the bit lines BL. Accordingly, the semiconductor memory device may improve in electrical properties.

Referring to FIG. 12, each of the bit lines BL may include tab portions TP and extension portions EP between the tab portions TP. Each of the tab portions TP may vertically overlap a pair of first and second semiconductor patterns SP1 and SP2 that are adjacent to one another in the third direction D3. For example, the tab portions TP that vertically overlap the pair of first and second semiconductor patterns SP1 and SP2 that are adjacent to one another in the third direction D3 may be connected to one another to constitute a single object. Thus, the extension portions EP may not be positioned between the pair of first and second semiconductor patterns SP1 and SP2 that are adjacent to one another in the third direction D3. In addition, each of the tab portions TP may have a planar area greater than that of the pair of first and second semiconductor patterns SP1 and SP2 that are adjacent to one another in the third direction D3.

When viewed in plan, each of the extension portions EP may have a linear or bar shape that extends in the second direction D2. When viewed in plan, each of the tab portions TP may have an oval shape that is inclined along the third direction D3. The present disclosed concepts, however, are not limited thereto, and each of the tab portions TP may have a planar shape, such as one or more of a tetragonal shape, a circular shape, and a polygonal shape.

Referring to FIG. 13, the bit lines BL may extend along the second direction D2 and may be spaced apart from one another in the first direction D1. The first semiconductor patterns SP1 and the second semiconductor patterns SP2 that correspond to the bit lines BL may be arranged in a zigzag fashion. The bit lines BL may extend meanderingly to correspondingly vertically overlap the first semiconductor patterns SP1 and the second semiconductor patterns SP2. When viewed in plan, each of the bit lines BL may have a wave-shaped profile.

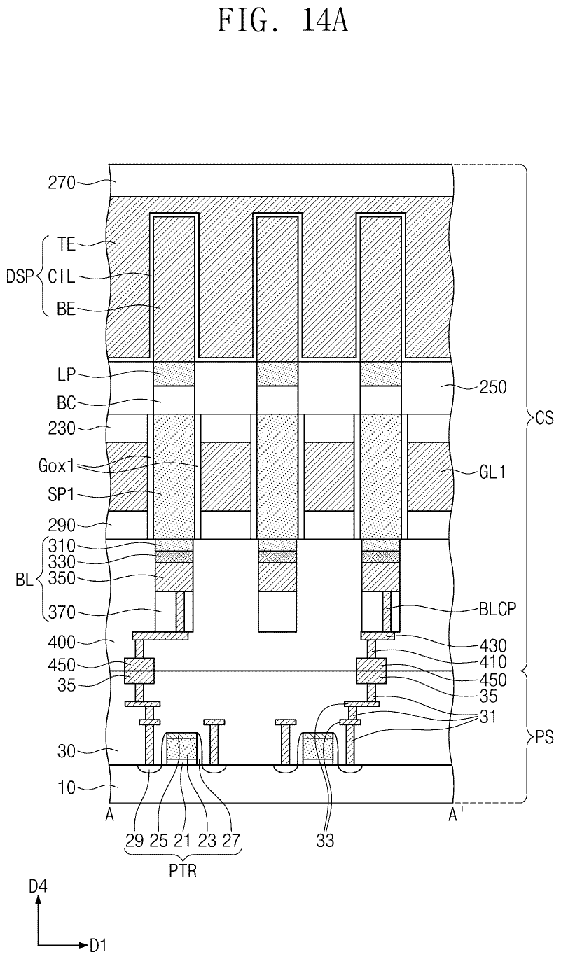

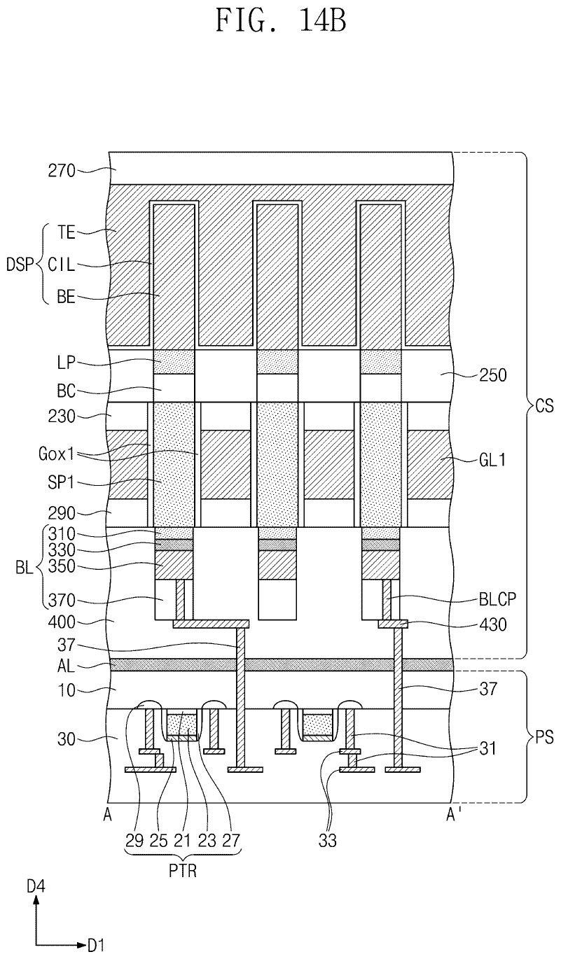

FIGS. 14A and 14B illustrate cross-sectional views taken along line A-A′ of FIG. 4, showing a semiconductor memory device according to some embodiments of the present disclosed concepts.

For convenience of explanation, omission will be made to avoid descriptions of the same features as those discussed with reference to FIGS. 4 and 5A to 5C, and differences will be described in detail below.

Referring to FIGS. 14A and 14B, the semiconductor memory device may further include a peripheral circuit structure PS that is positioned beneath and vertically overlaps the cell structure CS. The cell structure CS may be electrically connected to the peripheral circuit structure PS. The present disclosed concepts, however, are not limited thereto, and the peripheral circuit structure PS may be positioned above or on one side of the cell structure CS.

Referring to FIG. 14A, bit-line plugs BLCP may be provided in the lower dielectric layer 400. The bit-line plugs BLCP may penetrate portions of corresponding bit lines BL to have a connection with the corresponding bit lines BL. The bit-line plugs BLCP may be electrically connected to corresponding first bonding pads 450 through connection circuit lines 430 and connection circuit plugs 410 in the lower dielectric layer 400. For example, the connection circuit lines 430 and the connection circuit plugs 410 may include a conductive material, such as metal.

The lower dielectric layer 400 may be provided therein with the first bonding pads 450 adjacent to a bottom surface of the lower dielectric layer 400. The bottom surface of the lower dielectric layer 400 may expose bottom surfaces of the first bonding pads 450. For example, the bottom surface of the lower dielectric layer 400 may be coplanar with the bottom surfaces of the first bonding pads 450.

The peripheral circuit structure PS may be positioned on the bottom surface of the lower dielectric layer 400. The peripheral circuit structure PS may vertically overlap the lower dielectric layer 400. The peripheral circuit structure PS may include a peripheral circuit substrate 10, peripheral circuit transistors PTR on the peripheral circuit substrate 10, peripheral circuit plugs 31, peripheral circuit lines 33 electrically connected through the peripheral circuit plugs 31 to the peripheral circuit transistors PTR, and a first dielectric layer 30 that surrounds the peripheral circuit transistors PTR, the peripheral circuit plugs 31, and the peripheral circuit lines 33.

A peripheral circuit may be constituted by the peripheral circuit transistors PTR, the peripheral circuit plugs 31, and the peripheral circuit lines 33. Each of the peripheral circuit transistors PTR may include a peripheral gate dielectric layer 21, a peripheral gate electrode 23, a peripheral capping pattern 25, a peripheral gate spacer 27, and peripheral source/drain regions 29.

The peripheral gate dielectric layer 21 may be positioned between the peripheral gate electrode 23 and the peripheral circuit substrate 10. The peripheral capping pattern 25 may be positioned on the peripheral gate electrode 23. The peripheral gate spacer 27 may cover a sidewall of each of the peripheral gate dielectric layer 21, the peripheral gate electrode 23, and the peripheral capping pattern 25. The peripheral source/drain regions 29 may be positioned in the peripheral circuit substrate 10 adjacent to opposite sides of the peripheral gate electrode 23.

The peripheral circuit lines 33 may be electrically connected through the peripheral circuit plugs 31 to the peripheral circuit transistors PTR. For example, each of the peripheral circuit transistors PTR may be, an NMOS transistor, a PMOS transistor, or a gate-all-around type transistor, but the present disclosed concepts are not limited thereto. The peripheral circuit plugs 31 and the peripheral circuit lines 33 may include a conductive material, such as metal.

The first dielectric layer 30 may be provided on the peripheral circuit substrate 10. On the peripheral circuit substrate 10, the first dielectric layer 30 may cover the peripheral circuit transistors PTR, the peripheral circuit plugs 31, and the peripheral circuit lines 33. The first dielectric layer 30 may be formed of multiple layers. For example, the first dielectric layer 30 may include one or more of silicon oxide, silicon nitride, silicon oxynitride, and low-k dielectric.

The first dielectric layer 30 may be provided therein with second bonding pads 35 adjacent to a top surface of the first dielectric layer 30. The first dielectric layer 30 may not cover top surfaces of the second bonding pads 35. For example, the top surface of the first dielectric layer 30 may be coplanar with the top surfaces of the second bonding pads 35. The second bonding pads 35 may be electrically connected to the peripheral circuit transistors PTR through the peripheral circuit plugs 31 and the peripheral circuit lines 33.

The first bonding pads 450 may be correspondingly in contact with the second bonding pads 35. The bottom surfaces of the first bonding pads 450 may be correspondingly in contact with the top surfaces of the second bonding pads 35. The first and second bonding pads 450 and 35 may constitute an intermetallic hybrid bonding therebetween. In this description, the term “hybrid bonding” may denote a bonding in which two components of the same kind are merged at an interface therebetween. The first and second bonding pads 450 and 35 may thus constitute a single object without boundaries therebetween.

Referring to FIG. 14B, an interfacial layer AL may be provided between the cell structure CS and the peripheral circuit structure PS. The interfacial layer AL may be in contact with the peripheral circuit substrate 10 and the bottom surface of the lower dielectric layer 400. The peripheral circuit structure PS may include peripheral circuit vias 37 that are electrically connected to the peripheral circuit transistors PTR through the peripheral circuit plugs 31 and the peripheral circuit lines 33. The peripheral circuit vias 37 may penetrate the interfacial layer AL to have a connection with the connection circuit lines 430 of the cell structure CS. Therefore, the data storage patterns DSP of the cell structure CS may be electrically connected to the peripheral circuit transistors PTR of the peripheral circuit structure PS.

A dielectric layer may further be provided between the peripheral circuit substrate 10 and sidewalls of the peripheral circuit vias 37. Thus, the peripheral circuit vias 37 and the peripheral circuit substrate 10 may be electrically insulated from one another.

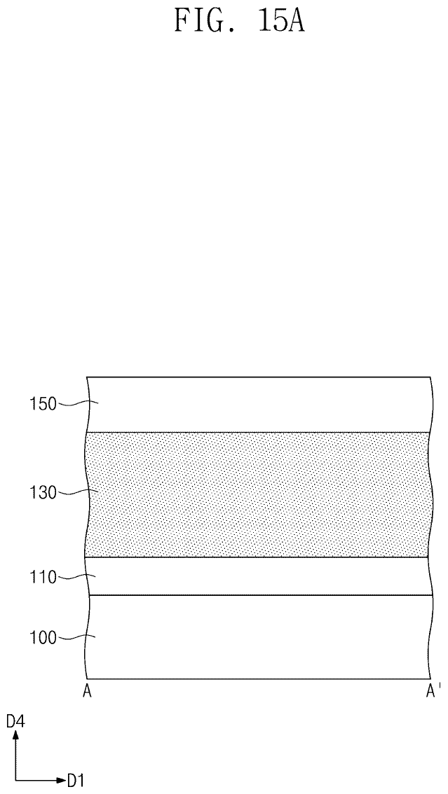

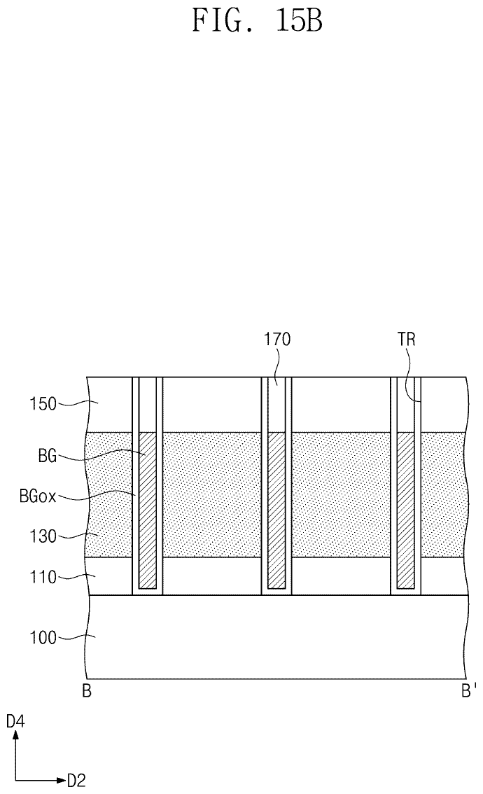

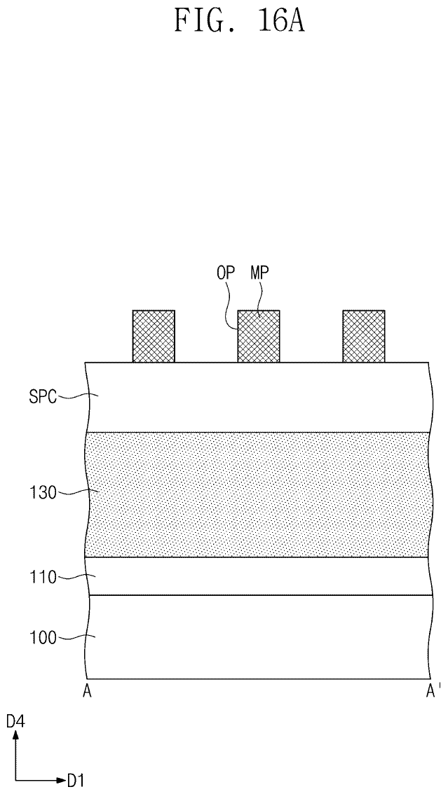

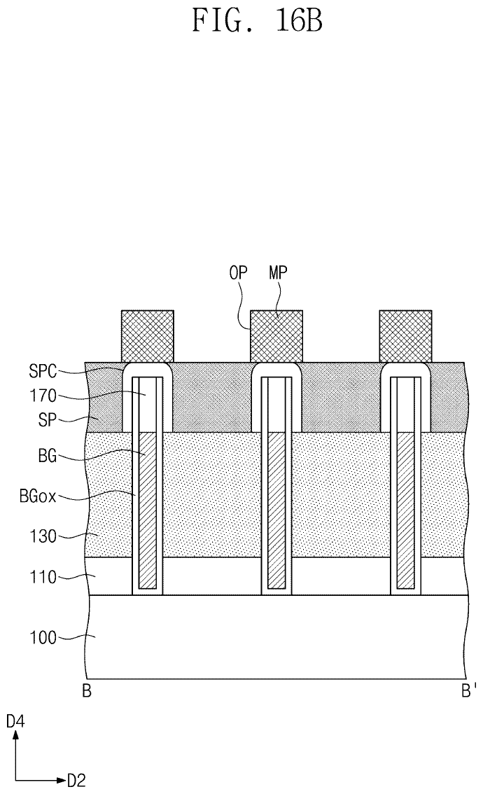

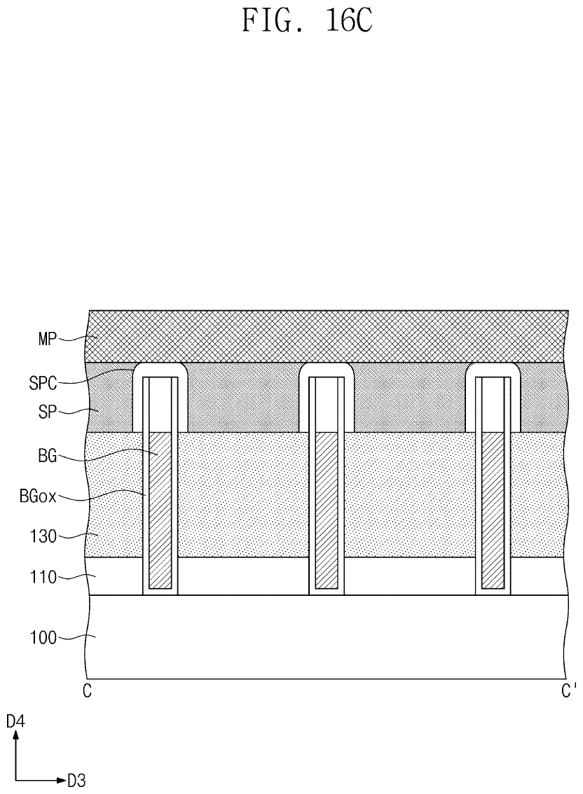

FIGS. 15A to 19B illustrate cross-sectional views showing a method of fabricating a semiconductor memory device according to some embodiments of the present disclosed concepts. FIGS. 15A, 16A, 17A, 18A, and 19A illustrate cross-sectional views taken along line A-A′ of FIG. 4. FIGS. 15B, 16B, 17B, 18B, and 19B illustrate cross-sectional views taken along line B-B′ of FIG. 4. FIG. 16C illustrates a cross-sectional view taken along line C-C′ of FIG. 4.

Referring to FIGS. 15A and 15B, a substrate 100 may be provided. For example, the substrate 100 may be a silicon wafer. A first preliminary dielectric layer 110, a semiconductor layer 130, and a second preliminary dielectric layer 150 each having an uniform thickness may be sequentially formed on the substrate 100.

A deposition process may be employed for the formation of the first preliminary dielectric layer 110, the semiconductor layer 130, and the second preliminary dielectric layer 150. For example, the deposition process may include one or more of a physical vapor deposition (PVD) process, a chemical vapor deposition (CVD) process, and an atomic layer deposition (ALD) process. The first preliminary dielectric layer 110 and the second preliminary dielectric layer 150 may include dielectric materials different from one another. According to embodiments, the first preliminary dielectric layer 110 may include silicon oxide, and the second preliminary dielectric layer 150 may include silicon nitride. The semiconductor layer 130 may include monocrystalline silicon. For example, the semiconductor layer 130 may include impurity-doped monocrystalline silicon or impurity-undoped monocrystalline silicon.

Trenches TR may be formed to penetrate the first preliminary dielectric layer 110, the semiconductor layer 130, and the second preliminary dielectric layer 150. Each of trenches TR may extend in a first direction D1 and may be spaced apart from one another in a second direction D2. A bottom surface of each of the trenches TR may expose a top surface of the substrate 100.

Back-gate dielectric layers BGox, back-gate lines BG, and back-gate capping layers 170 may be sequentially formed in the trenches TR. The back-gate dielectric layers BGox may have their uniform thicknesses covering inner walls of the trenches TR. The back-gate lines BG may fill lower portions of the trenches TR. On the back-gate lines BG, the back-gate capping layers 170 may fill upper portions of the trenches TR. The back-gate lines BG may extend in the first direction D1 along the trenches TR and may be spaced apart from one another in the second direction D2.

Referring to FIGS. 16A, 16B, and 16C, the second preliminary dielectric layer 150 may be removed. The second preliminary dielectric layer 150 may include a material having an etch selectivity with respect to the back-gate dielectric layers BGox and the back-gate capping layers 170. Thus, the back-gate dielectric layers BGox and the back-gate capping layers 170 are maintained, and the second preliminary dielectric layer 150 may be selectively removed. The removal of the second preliminary dielectric layer 150 may expose the semiconductor layer 130.

On the semiconductor layer 130, spacers SPC may be formed to vertically overlap the back-gate lines BG. The formation of the spacers SPC may include forming a spacer layer having an uniform thickness on the semiconductor layer 130, and performing an etch-back process on the spacer layer. The spacers SPC may correspondingly cover the back-gate capping layers 170 and the back-gate dielectric layers BGox.

Support patterns SP may be formed between the spacers SPC. The formation of the support patterns SP may include depositing a support layer on an entire surface of the substrate 100 and performing a planarization process on the support layer. Thus, top surfaces of the support patterns SP may be located at the same level as that of top surfaces of the spacers SPC. The spacers SPC may be exposed through the support patterns SP. According to embodiments, the support patterns SP may cover the spacers SPC, while having top surfaces at a higher level than that of top surfaces of the spacers SPC.

Mask patterns MP may be formed on the support patterns SP and the spacers SPC. Each of the mask patterns MP may extend in a third direction D3 substantially cross to the first direction D1 and the second direction D2 and substantially parallel to the top surface of the substrate 100. The mask patterns MP may have openings OP that expose the support patterns SP and the spacers SPC. Likewise the mask patterns MP, the openings OP may extend in the third direction D3. When viewed in plan, the mask patterns MP and the openings OP may extend in the third direction D3 and may be alternately positioned.

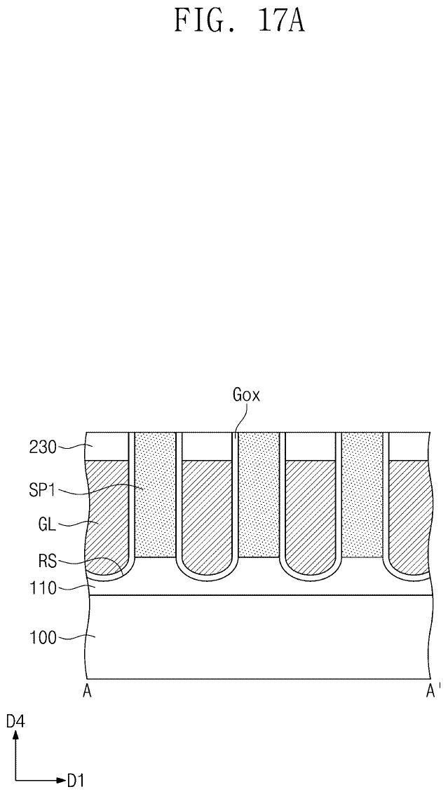

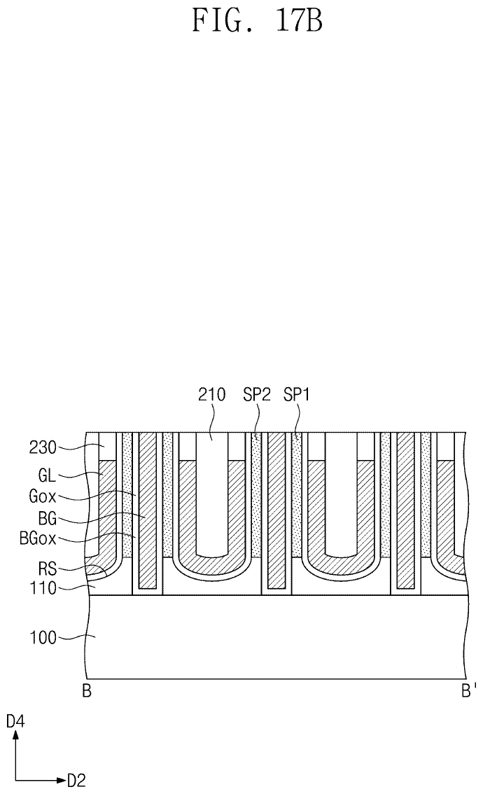

Referring to FIGS. 17A and 17B, an etching process may be performed in which the mask patterns MP and the spacers SPC are used as an etching mask. The semiconductor layer 130 may be partially removed through the etching process to form first semiconductor patterns SP1 and second semiconductor patterns SP2. For example, the spacers SPC may separate the first semiconductor patterns SP1 and the second semiconductor patterns SP2 from one another in the second direction D2. The mask patterns MP may allow the first semiconductor patterns SP1 and the second semiconductor patterns SP2 to be spaced apart from one another in a direction that is substantially parallel to the top surface of the substrate 100 and orthogonal to the third direction D3. When viewed in plan, the first semiconductor patterns SP1 and the second semiconductor patterns SP2 may be arranged in a zigzag fashion.

The etching process for forming the first and second semiconductor patterns SP1 and SP2 may include partially removing the first preliminary dielectric layer 110. The etching process may form recess regions RS on an upper portion of the first preliminary dielectric layer 110. The recess regions RS may cause the first preliminary dielectric layer 110 to have a top surface lower than bottom surfaces of the first and second semiconductor patterns SP1 and SP2. The recess regions RS may not expose the top surface of the substrate 100, but the present disclosed concepts are not limited thereto.

Between the first semiconductor patterns SP1 and the second semiconductor patterns SP2, a gate dielectric layer Gox may be formed to cover the recess regions RS. The gate dielectric layer Gox having an uniform thickness may extend into the recess regions RS of the first preliminary dielectric layer 110, while covering the first semiconductor patterns SP1 and the second semiconductor patterns SP2. For example, the gate dielectric layer Gox may be formed of silicon oxide, silicon oxynitride, silicon nitride, high-k dielectric, or any combination thereof.

A gate line GL may be formed on the gate dielectric layer Gox. The gate line GL having a regular thickness may extend into the recess regions RS, while covering the gate dielectric layer Gox. For example, the gate line GL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof, but the present disclosed concepts are not limited thereto.

Capping dielectric patterns 210 may be formed on the gate line GL. The capping dielectric patterns 210 may fill an empty space, while covering the gate line GL.

A metal etch-back process may be performed on the back-gate lines BG and the gate line GL. The metal etch-back process may selectively remove the back-gate lines BG and the gate line GL each including a metallic material. Thus, the capping dielectric patterns 210, the first semiconductor patterns SP1, and the second semiconductor patterns SP2 may remain intact. The metal etch-back process may recess an upper portion of each of the back-gate lines BG and the gate line GL.

An upper buried layer 230 may be formed in the recessed upper portion of each of the back-gate lines BG and the gate line GL. The upper buried layer 230 may be positioned on the back-gate lines BG and the gate line GL. The upper buried layer 230 may have a top surface located at the same level as that of top surfaces of the first semiconductor patterns SP1, the second semiconductor patterns SP2, and the capping dielectric patterns 210.

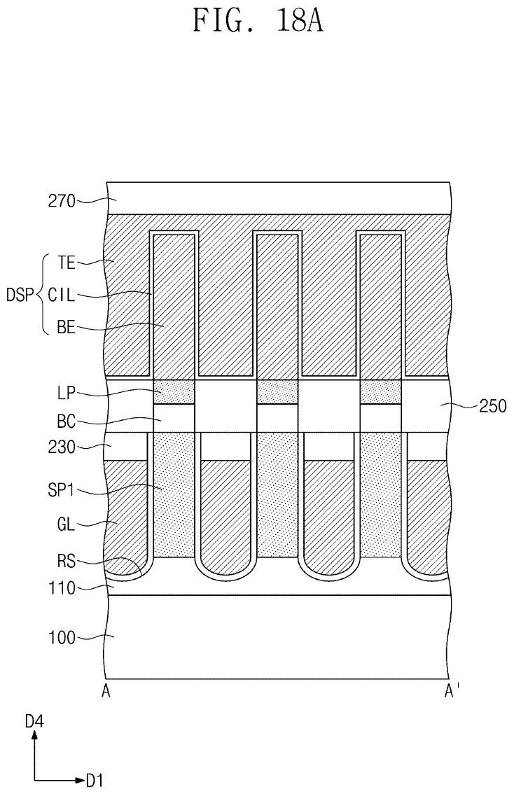

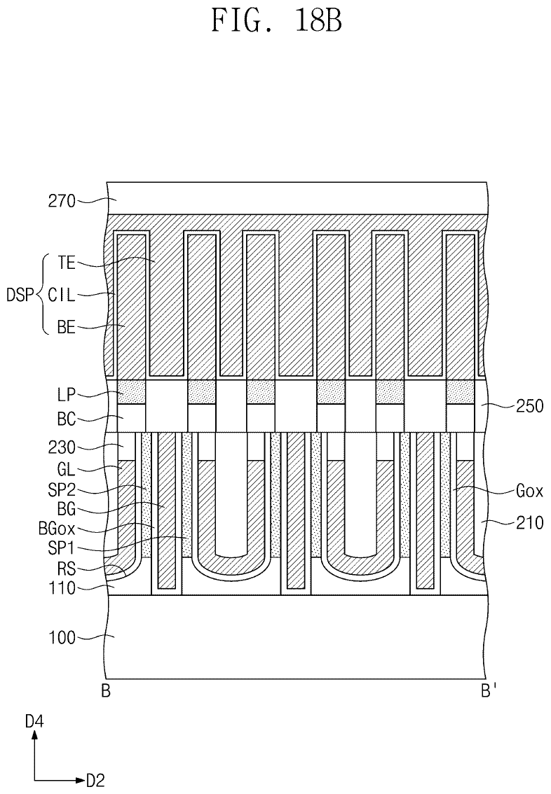

Referring to FIGS. 18A and 18B, an interlayer dielectric layer 250 may be formed on the first semiconductor patterns SP1 and the second semiconductor patterns SP2. The interlayer dielectric layer 250 may cover the first semiconductor patterns SP1, the second semiconductor patterns SP2, and the capping dielectric patterns 210. For example, the interlayer dielectric layer 250 may be in contact with the upper buried layer 230, the back-gate dielectric layers BGox, and the gate dielectric layer Gox.

The interlayer dielectric layer 250 may be patterned to sequentially form lower contacts BC and landing pads LP in the interlayer dielectric layer 250. The lower contacts BC may correspondingly vertically overlap corresponding landing pads LP. The lower contacts BC may be correspondingly in contact with the first semiconductor patterns SP1 and the second semiconductor patterns SP2. The lading pads LP may be in contact with corresponding bottom electrodes BE which will be discussed below. According to embodiments, at least ones of the lower contacts BC and the landing pads LP may be shifted in the first direction D1, the second direction D2, and/or the third direction D3 with respect to the first semiconductor patterns SP1 and the second semiconductor patterns SP2.

Data storage patterns DSP may be formed on the interlayer dielectric layer 250. The formation of the data storage patterns DSP may include forming bottom electrodes BE, forming a capacitor dielectric layer CIL having an uniform thickness that covers the bottom electrodes BE, and a top electrode TE that covers the capacitor dielectric layer CIL.

Each of the bottom electrodes BE may extend in a fourth direction D4 from the interlayer dielectric layer 250. The bottom electrodes BE may be spaced apart from one another in the first direction D1 and the second direction D2. When viewed in plan, the bottom electrodes BE may be arranged in a honeycomb fashion on the interlayer dielectric layer 250. There may thus be a reduction in electrical interference between the bottom electrodes BE.

An upper dielectric layer 270 may be formed on the data storage patterns DSP. The upper dielectric layer 270 may cover the top electrode TE of the data storage patterns DSP, protecting the data storage patterns DSP.

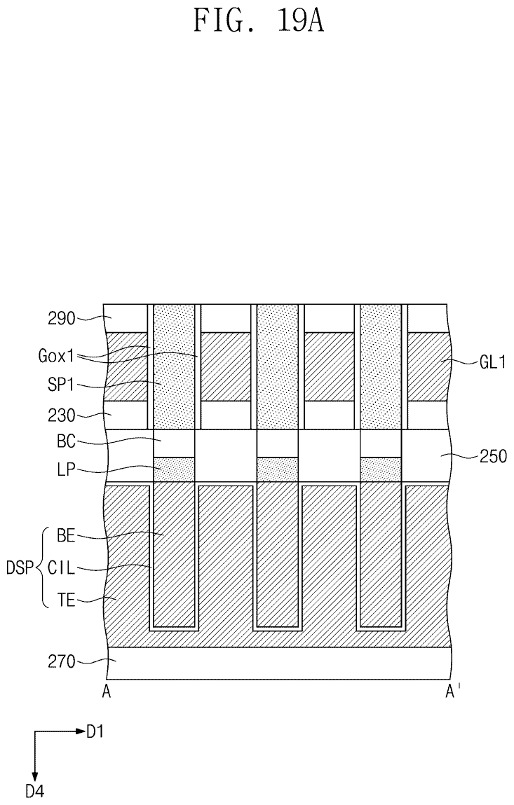

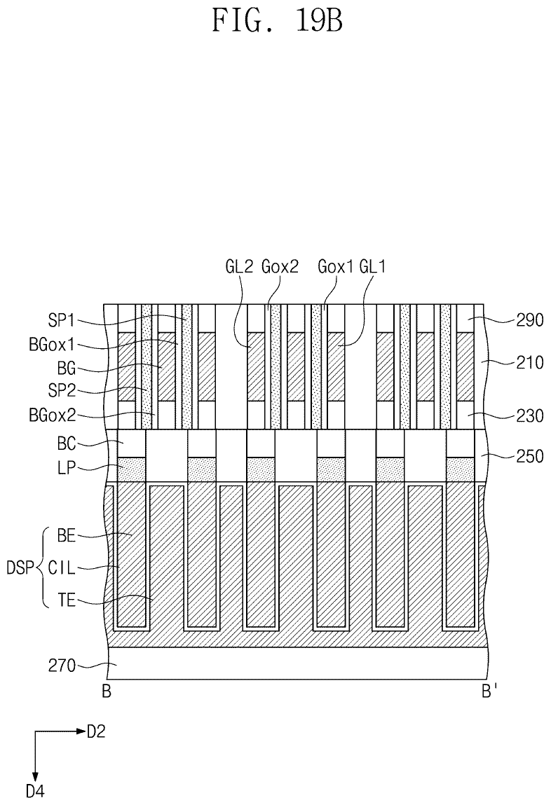

Referring to FIGS. 19A and 19B, the substrate 100 may be turned upside down. Thus, the upper dielectric layer 270 may be positioned at a lower level than that of the substrate 100. Under the state where the substrate 100 is flipped, a polishing process may be performed on the substrate 100. The polishing process may continue until the first and second semiconductor patterns SP1 and SP2 are exposed.

The polishing process may completely remove the substrate 100 and the first preliminary dielectric layer 110. In addition, the polishing process may partially remove the back-gate dielectric layer BGox, the gate line GL, and the gate dielectric layer Gox, such that each of the back-gate dielectric layer BGox, the gate line GL, and the gate dielectric layer Gox may be divided into a plurality of pieces. For example, the back-gate dielectric layer BGox may be formed into first back-gate dielectric layers BGox1 and second back-gate dielectric layers BGox2. The gate line GL may be formed into first gate lines GL1 and second gate lines GL2. The gate dielectric layer Gox may be formed into first gate dielectric layers Gox1 and second gate dielectric layers Gox2.

A metal etch-back process may be performed on the back-gate lines BG, the first gate lines GL1, and the second gate lines GL2. The metal etch-back process may selectively remove the back-gate lines BG, the first gate lines GL1, and the second gate lines GL2 each including a metallic material. The metal etch-back process may recess a lower portion (e.g., an upper portion when the substrate 100 is flipped) of each of the back-gate lines BG, the first gate lines GL1, and the second gate lines GL2.

A lower buried layer 290 may be formed in the recessed lower portion of each of the back-gate lines BG, the first gate lines GL1, and the second gate lines GL2. The lower buried layer 290 may be positioned beneath each of the back-gate lines BG, the first gate lines GL1, and the second gate lines GL2. The lower buried layer 290 may have a bottom surface (e.g., a top surface when the substrate 100 is flipped) located at the same level as that of the bottom surfaces of the first semiconductor patterns SP1, the second semiconductor patterns SP2, and the capping dielectric patterns 210.

Referring back to FIGS. 5A, 5B, and 5C, bit lines BL may be formed under the state where the substrate 100 is flipped. The formation of the bit lines BL may include forming a bit-line layer, forming a mask pattern on the bit-line layer, and using the mask pattern as an etching mask to pattern the bit-line layer. The formation of the bit-line layer may include sequentially forming a first line 310, a second line 320, a third line 350, and a capping line 370. This may form the bit lines BL each including the first line 310, the second line 330, the third line 350, and the capping line 370 that are stacked in the fourth direction D4. The bit lines BL may extend in the third direction D3, and may correspondingly vertically overlap the first semiconductor patterns SP1 and the second semiconductor patterns SP2.

A lower dielectric layer 400 may be formed to cover the bit lines BL. The lower dielectric layer 400 may cover the bit lines BL, the capping dielectric patterns 210, and the lower buried layer 290.

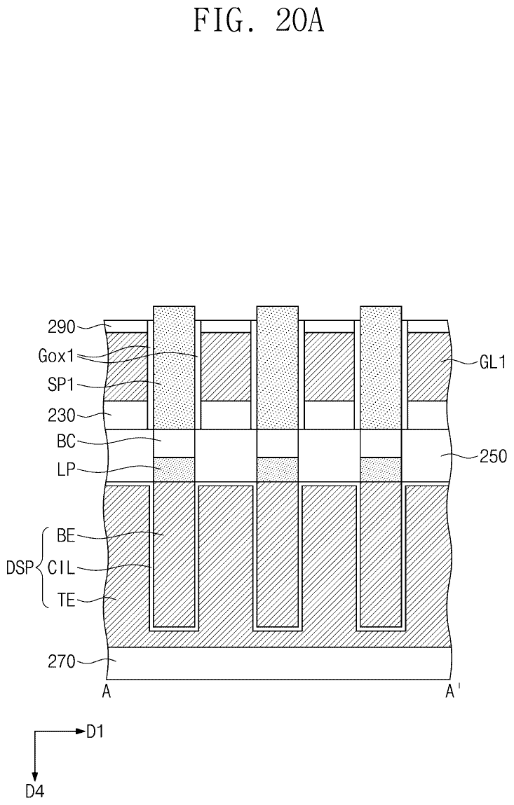

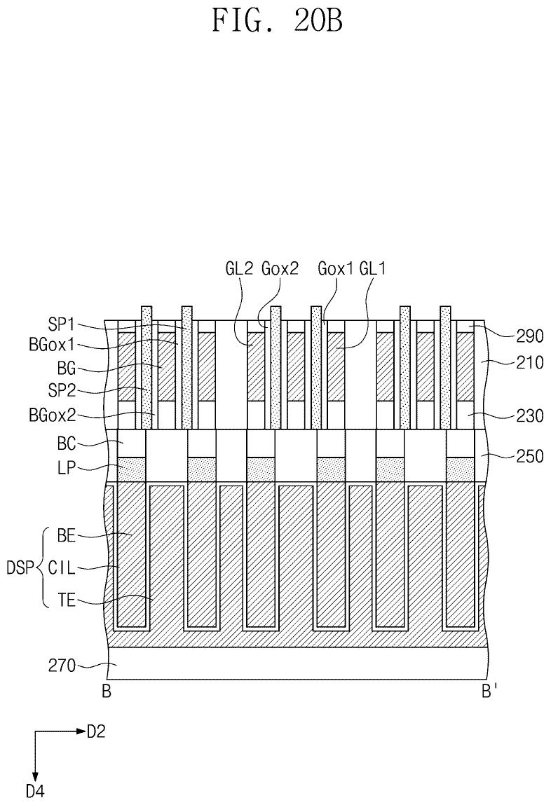

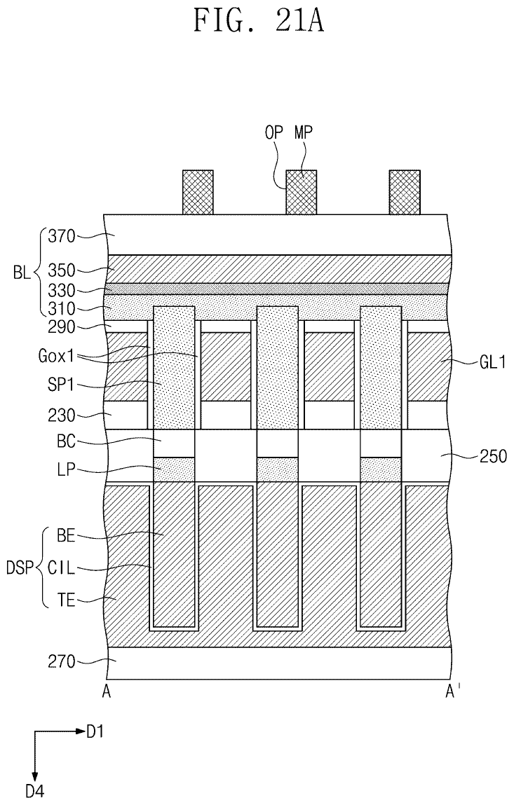

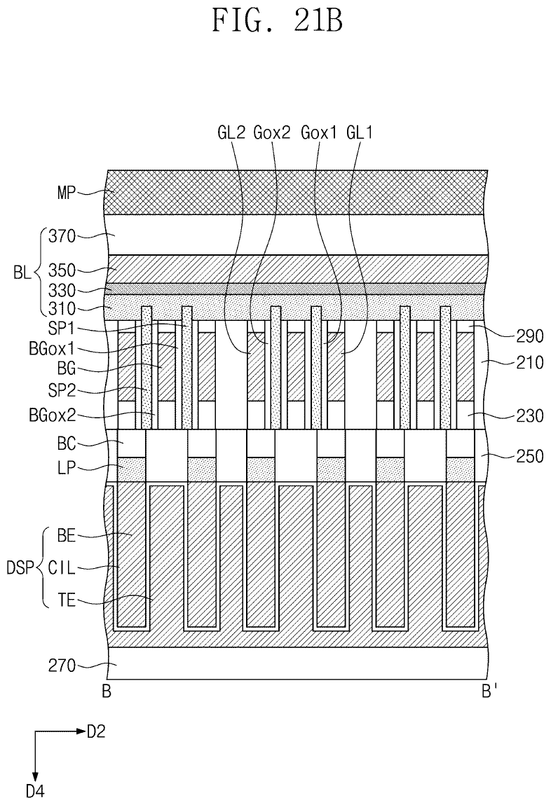

FIGS. 20A to 21B illustrate cross-sectional views showing a method of fabricating a semiconductor memory device according to some embodiments of the present disclosed concepts. FIGS. 20A and 21 A illustrate cross-sectional views taken along line A-A′ of FIG. 7. FIGS. 20B and 21B illustrate cross-sectional views taken along line B-B′ of FIG. 7.

Referring to FIGS. 20A and 20B, after the formation of the back-gate lines BG, the first gate lines GL1, the second gate lines GL2, the first semiconductor patterns SP1, the second semiconductor patterns SP2, and the data storage patterns DSP, a semiconductor memory device may be turned upside down. The formation of the back-gate lines BG, the first gate lines GL1, the second gate lines GL2, the first semiconductor patterns SP1, the second semiconductor patterns SP2, and the data storage patterns DSP may be substantially the same as those discussed with reference to FIGS. 15A to 19B.

A recess process may be carried out. For example, the recess process may selectively remove a dielectric material. The recess process may partially remove each of the first back-gate dielectric layers BGox1, the second back-gate dielectric layers BGox2, the first gate dielectric layers Gox1, the second gate dielectric layers Gox2, the capping dielectric patterns 210, and the lower buried layer 290. Differently, the first semiconductor patterns SP1 and the second semiconductor patterns SP2 may remain intact.

The recess process may cause the first and second semiconductor patterns SP1 and SP2 to have their shapes that protrude from the lower buried layer 290. A protruding portion of each of the first and second semiconductor patterns SP1 and SP2 may protrude in a vertical direction (e.g., a direction counter to the fourth direction D4).

Referring to FIGS. 21A and 21B, a first line 310 may be formed to cover the protruding portion of each of the first and second semiconductor patterns SP1 and SP2. A second line 330, a third line 350, and a capping line 370 may be sequentially formed on the first line 310. Thus, the first semiconductor patterns SP1 and the second semiconductor patterns SP2 may be three-dimensionally in contact with the first line 310.

Mask patterns MP may be formed on the capping line 370. The mask patterns MP may extend in the second direction D2 and may be spaced apart from one another in the first direction D1. The mask patterns MP may have openings OP that expose the capping line 370. The openings OP may extend in the second direction D2 along the mask patterns MP.

Referring back to FIGS. 8A and 8B, an etching process may be performed in which the mask patterns MP are used as an etching mask. The etching process may partially remove the first line 310, the second line 330, the third line 350, and the capping line 370 that vertically overlap the openings OP of the mask patterns MP. Thus, bit lines BL may be formed to be spaced apart from one another in the first direction D1 and to extend in the second direction D2. The etching process may further remove a portion of each of the first and second semiconductor patterns SP1 and SP2 that vertically overlap the openings OP of the mask patterns MP.

After the formation of the bit lines BL, a lower dielectric layer 400 may be formed to cover the bit lines BL.

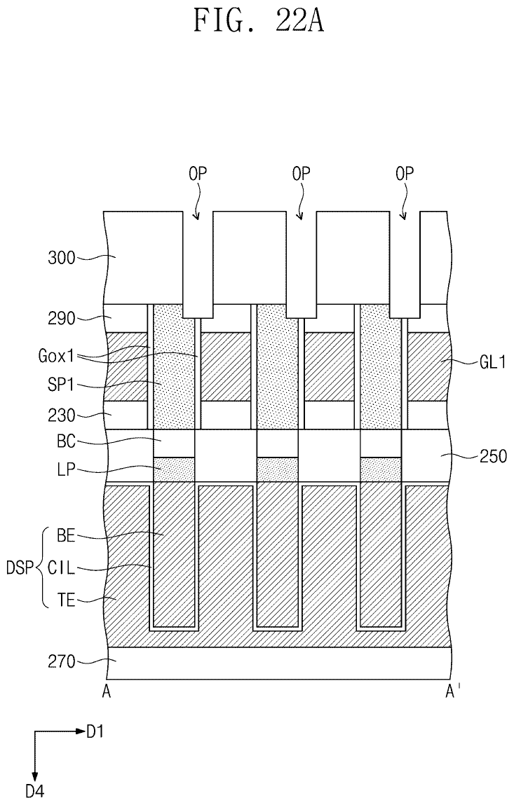

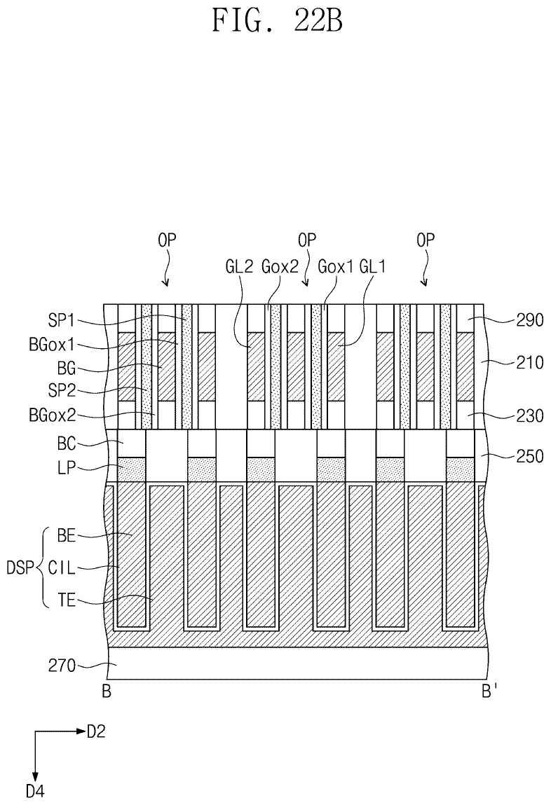

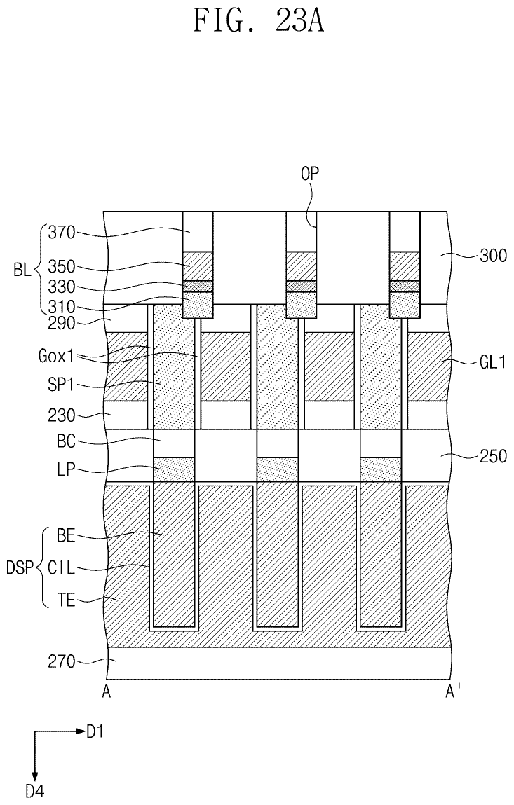

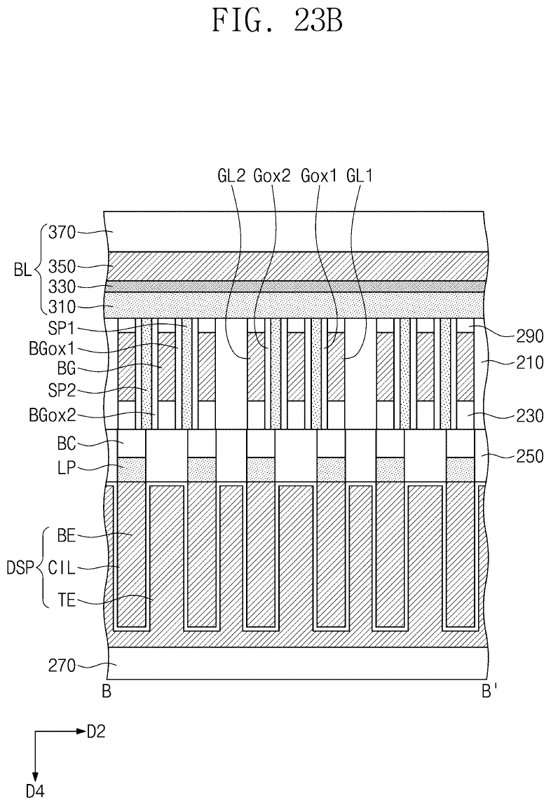

FIGS. 22A to 23B illustrate cross-sectional views showing a method of fabricating a semiconductor memory device according to some embodiments of the present disclosed concepts. FIGS. 22A and 23A illustrate cross-sectional views taken along line A-A′ of FIG. 7. FIGS. 22B and 23B illustrate cross-sectional views taken along line B-B′ of FIG. 7.

Referring to FIGS. 22A and 22B, after the formation of the back-gate lines BG, the first gate lines GL1, the second gate lines GL2, the first semiconductor patterns SP1, the second semiconductor patterns SP2, and the data storage patterns DSP, a semiconductor memory device may be turned upside down. The formation of the back-gate lines BG, the first gate lines GL1, the second gate lines GL2, the first semiconductor patterns SP1, the second semiconductor patterns SP2, and the data storage patterns DSP may be substantially the same as those discussed with reference to FIGS. 15A to 19B.

A dielectric pattern 300 may be formed on the lower buried layer 290. The formation of the dielectric pattern 300 may include forming a dielectric layer on the lower buried layer 290 and using an etching process to pattern the dielectric layer. The patterning using the etching process may form openings OP within the dielectric pattern 300. The openings OP of the dielectric pattern 300 may extend in the second direction D2 and may be spaced apart from one another in the first direction D1. The etching process may cause a further removal of the first semiconductor patterns SP1 and the second semiconductor patterns SP2. Thus, the first semiconductor patterns SP1, the second semiconductor patterns SP2, and the lower buried layer 290 may be partially removed.

Referring to FIGS. 23A and 23B, bit lines BL may be correspondingly formed in the openings OP of the dielectric pattern 300. The formation of the bit lines BL may include sequentially forming a first line 310, a second line 330, a third line 350, and a capping line 370 in each of the openings OP. The first line 310 may fill a space where the first semiconductor pattern SP1, the second semiconductor pattern SP2, and the lower buried layer 290 are partially removed. Thus, the first line 310 may be three-dimensionally in contact with the first semiconductor patterns SP1 and the second semiconductor patterns SP2.

Referring back to FIGS. 9A and 9B, the dielectric pattern 300 may be removed. The dielectric pattern 300 may include a material having an etch selectivity with respect to the bit lines BL. Thus, the dielectric pattern 300 may be selectively removed while the bit lines BL remain intact.

After the removal of the dielectric pattern 300, a lower dielectric layer 400 may be formed to cover the bit lines BL.

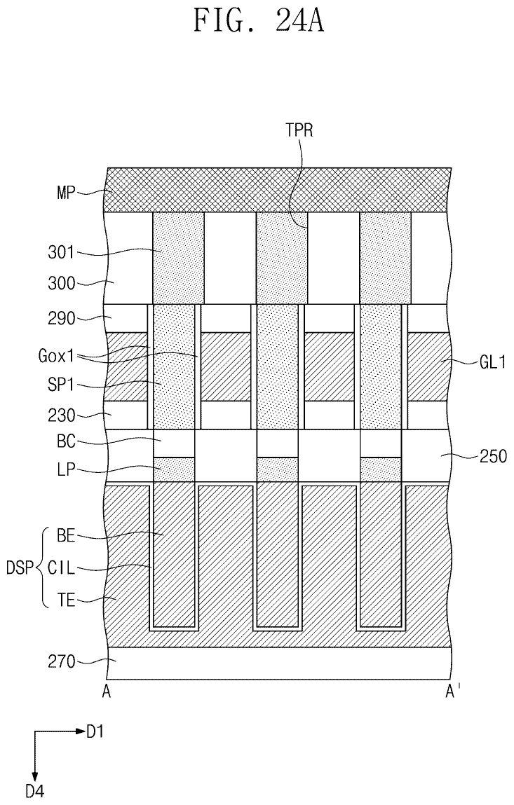

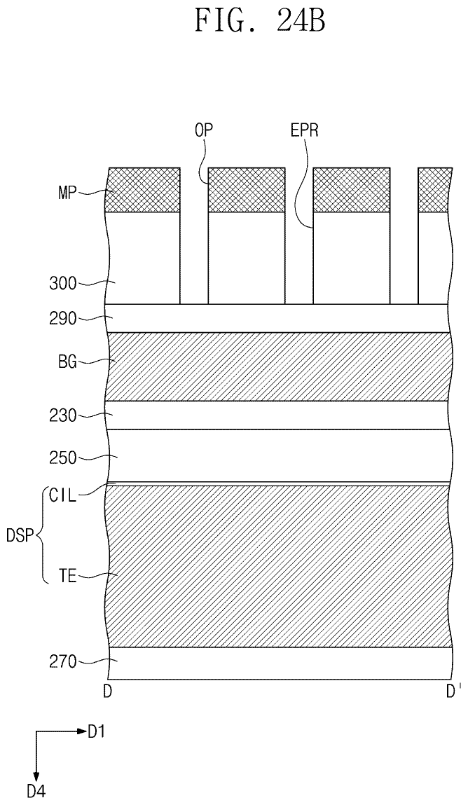

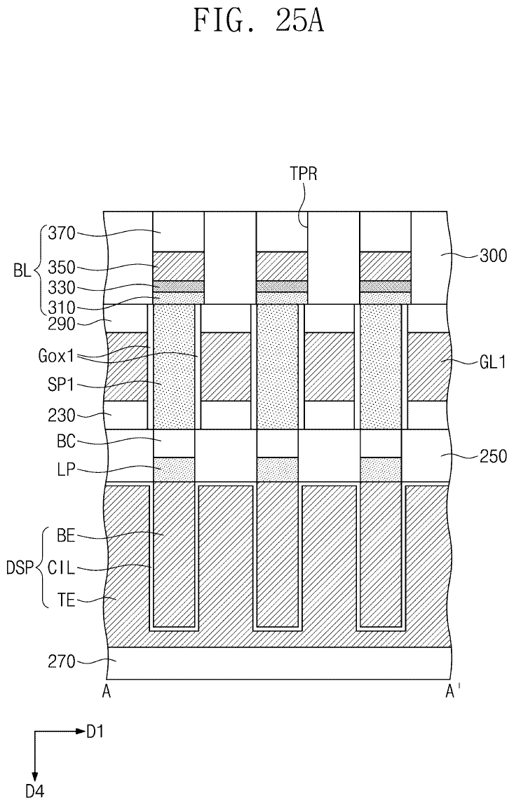

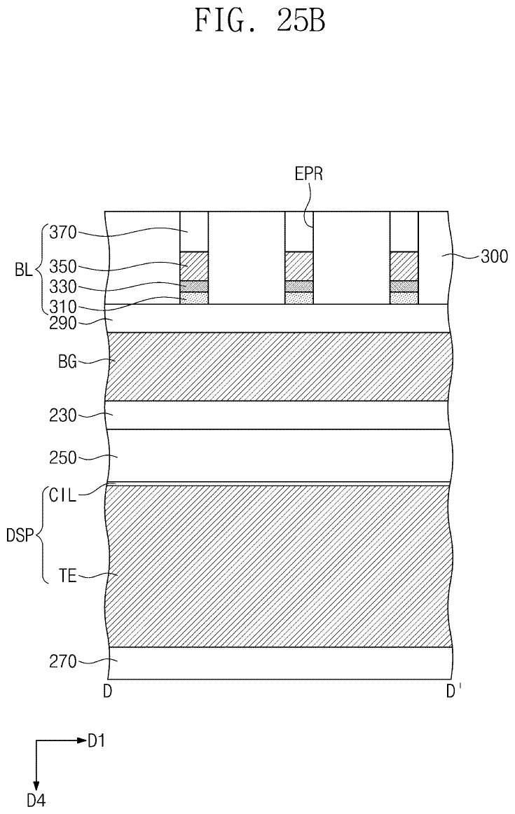

FIGS. 24A to 25B illustrate cross-sectional views showing a method of fabricating a semiconductor memory device according to some embodiments of the present disclosed concepts. FIGS. 24A and 25A illustrate cross-sectional views taken along line A-A′ of FIG. 10. FIGS. 24B and 25B illustrate cross-sectional views taken along line D-D′ of FIG. 10.

Referring to FIGS. 24A and 24B, after the formation of the back-gate lines BG, the first gate lines GL1, the second gate lines GL2, the first semiconductor patterns SP1, the second semiconductor patterns SP2, and the data storage patterns DSP, a semiconductor memory device may be turned upside down. The formation of the back-gate lines BG, the first gate lines GL1, the second gate lines GL2, the first semiconductor patterns SP1, the second semiconductor patterns SP2, and the data storage patterns DSP may be substantially the same as those discussed with reference to FIGS. 15A to 19B.

A dielectric pattern 300 having tab regions TPR may be formed on the lower buried layer 290, and a filling pattern 301 may be formed in the tab regions TPR of the dielectric pattern 300. The tab regions TPR of the dielectric pattern 300 may be areas where tab portions TP of bit lines BL are formed as discussed below. For example, as the filling pattern 301 is formed in the tab regions TPR of the dielectric pattern 300, the dielectric pattern 300 may be prevented from collapse caused by an etching process in which mask patterns MP are used as discussed below.

The formation of the dielectric pattern 300 and the filling pattern 301 may include forming a dielectric layer on the lower buried layer 290, patterning the dielectric layer to form the dielectric pattern 300 having the tab regions TPR, forming a filling layer to fill the tab regions TPR of the dielectric pattern 300, and performing on the filling layer a planarization process to expose the dielectric pattern 300. Thus, a top surface of the dielectric pattern 300 and a top surface of the filling pattern 301 may be coplanar with one another. For example, the dielectric pattern 300 and the filling pattern 301 may include dielectric materials different from one another, and each of the dielectric pattern 300 and the filling pattern 301 may have an etch selectivity different from that of the other.

Mask patterns MP may be formed on the dielectric pattern 300 and the filling pattern 301. The mask patterns MP may extend in the second direction D2 and may be arranged in the first direction D1. The mask patterns MP may have openings OP that expose the dielectric pattern 300.

An etching process may be performed in which the mask patterns MP are used as an etching mask. The etching process may partially remove the dielectric pattern 300 that is exposed through the openings OP of the mask patterns MP. Therefore, extension regions EPR may be formed in the dielectric pattern 300. The extension regions EPR of the dielectric pattern 300 may be areas where extension portions EP of bit lines BL are formed as discussed below. For example, the extension regions EPR of the dielectric pattern 300, which correspond to the openings OP of the mask patterns MP, may vertically overlap one another.

Referring to FIGS. 25A and 25B, the mask patterns MP and the filling pattern 301 may be sequentially removed. As the dielectric pattern 300 includes a material having an etch selectivity with respect to the filling pattern 301, the filling pattern 301 may be selectively removed while the dielectric pattern 300 remains.

The first semiconductor patterns SP1 and the second semiconductor patterns SP2 may be externally exposed through the tab regions TPR of the dielectric pattern 300. The lower buried layer 290 may be externally exposed through the extension regions EPR of the dielectric pattern 300. A width in the first direction D1 of each of the tab regions TPR may be greater than a width in the first direction D1 of each of the extension regions EPR.

Bit lines BL including tab portions TP and extension portions EP may be formed in the dielectric pattern 300. The tab portions TP of bit lines BL may be formed in the tab regions TPR of the dielectric pattern 300. The extension portions EP of the bit lines BL may be formed in the extension regions EPR of the dielectric pattern 300. In addition, the formation of the tab portions TP and the extension portions EP of the bit lines BL may include sequentially forming a first line 310, a second line 330, a third line 350, and a capping line 370.

Referring back to FIGS. 11A and 11B, the dielectric pattern 300 may be removed. The dielectric pattern 300 may include a material having an etch selectivity with respect to the bit lines BL. Thus, the dielectric pattern 300 may be selectively removed while the bit lines BL remain intact.

After the removal of the dielectric pattern 300, a lower dielectric layer 400 may be formed to cover the bit lines BL.

A semiconductor memory device according to some embodiments of the present disclosed concepts may include a bit line connected to a pair of semiconductor patterns that are adjacent to one another in a diagonal direction. The bit line of the present disclosed concepts may be provided in various shapes. In addition, the bit line may be easily in contact with the semiconductor patterns. Accordingly, the semiconductor memory device may improve in electrical properties.

Although the present invention has been described in connection with the embodiments of the present disclosed concepts illustrated in the accompanying drawings, it will be understood to those skilled in the art that various changes and modifications may be made without departing from the technical spirit and essential feature of the present disclosed concepts. It therefore will be understood that the embodiments described above are just illustrative but not limitative in all aspects.

What is claimed is

1. A semiconductor memory device, comprising:
a lower dielectric layer;
a bit line in the lower dielectric layer;
a back-gate line that extends in a first direction on the lower dielectric layer, the back-gate line having a first lateral surface and a second lateral surface that face one another in a second direction substantially cross to the first direction;
a first semiconductor pattern on the first lateral surface of the back-gate line; and
a second semiconductor pattern on the second lateral surface of the back-gate line,
wherein the first semiconductor pattern and the second semiconductor pattern are adjacent to one another in a third direction substantially cross to the first direction and the second direction,
wherein the first direction, the second direction, and the third direction are substantially parallel to a top surface of the lower dielectric layer, and
wherein the bit line is connected to the first semiconductor pattern and the second semiconductor pattern.

2. The semiconductor memory device of claim 1, wherein:
the first direction and the second direction are substantially orthogonal to one another, and
the bit line extends in the third direction.

3. The semiconductor memory device of claim 1, wherein the bit line vertically overlaps at least a portion of each of the first semiconductor pattern and the second semiconductor pattern.

4. The semiconductor memory device of claim 1, further comprising:
a first gate line on the first lateral surface of the back-gate line; and
a second gate line on the second lateral surface of the back-gate line,
wherein the first semiconductor pattern is between the back-gate line and the first gate line, and
wherein the second semiconductor pattern is between the back-gate line and the second gate line.

5. The semiconductor memory device of claim 4, wherein:
the first gate line extends onto first, second, and third surfaces of the first semiconductor pattern, and
the second gate line extends onto first, second, and third surfaces of the second semiconductor pattern.

6. The semiconductor memory device of claim 1, wherein the bit line extends in the second direction.

7. The semiconductor memory device of claim 6, wherein at least a portion of each of the first semiconductor pattern and the second semiconductor pattern extends into the bit line.

8. The semiconductor memory device of claim 6, wherein at least a portion of the bit line extends into the first semiconductor pattern and the second semiconductor pattern.

9. The semiconductor memory device of claim 1, wherein the bit line comprises:
tab portions that vertically overlap the first semiconductor pattern and the second semiconductor pattern; and
an extension portion connected to the tab portions.

10. The semiconductor memory device of claim 9, wherein the tab portions are connected to one another to constitute a single object.

11. A semiconductor memory device, comprising:
a lower dielectric layer;
bit lines in the lower dielectric layer;
back-gate lines that extend in a first direction on the lower dielectric layer;
first semiconductor patterns on first lateral surfaces of the back-gate lines; and
second semiconductor patterns on second lateral surfaces of the back-gate lines,
wherein each of the bit lines comprises:
tab portions that vertically overlap the first semiconductor patterns and the second semiconductor patterns; and
extension portions between the tab portions,
wherein each of the extension portions extends in a second direction substantially cross to the first direction.

12. The semiconductor memory device of claim 11, wherein the tab portions of each of the bit lines are spaced apart from one another in the second direction.

13. The semiconductor memory device of claim 11, wherein, when viewed in plan, the tab portions are arranged in a zigzag fashion.

14. The semiconductor memory device of claim 11, wherein among the first semiconductor patterns and the second semiconductor patterns, first and second semiconductor patterns that are adjacent to one another in a third direction are connected to one of the tab portions,
wherein the third direction is substantially parallel to a top surface of the lower dielectric layer and is substantially cross to the first direction and the second direction.

15. The semiconductor memory device of claim 11, wherein a width in the first direction of each of the tab portions is greater than a width in the first direction of each of the extension portions.

16. A semiconductor memory device, comprising:
a peripheral circuit structure comprising peripheral circuits on a substrate; and
a cell structure electrically connected to the peripheral circuit structure,
wherein the cell structure comprises:
a lower dielectric layer;
bit lines in the lower dielectric layer;
back-gate lines that extend in a first direction on the lower dielectric layer;
first gate lines on first lateral surfaces of the back-gate lines;
second gate lines on second lateral surfaces of the back-gate lines;
first semiconductor patterns between the back-gate lines and the first gate lines;
second semiconductor patterns between the back-gate lines and the second gate lines; and
data storage patterns on the first semiconductor patterns and the second semiconductor patterns,
wherein the first gate lines and the second gate lines are spaced apart from one another in a second direction substantially cross to the first direction, and
wherein, among the first semiconductor patterns and the second semiconductor patterns, first and second semiconductor patterns that are adjacent to one another in a third direction are connected to one of the bit lines, the third direction being substantially cross to the first direction and the second direction.

17. The semiconductor memory device of claim 16, wherein
the data storage patterns correspondingly vertically overlap the first semiconductor patterns and the second semiconductor patterns, and
when viewed in plan, the data storage patterns are arranged in a honeycomb fashion.

18. The semiconductor memory device of claim 16, wherein a thickness in the second direction of each of the first gate lines and the second gate lines is changed along the first direction.

19. The semiconductor memory device of claim 16, wherein each of the bit lines extends in the third direction.

20. The semiconductor memory device of claim 16, wherein
each of the first semiconductor patterns and the second semiconductor patterns extends in a direction perpendicular to a top surface of the lower dielectric layer, and
when viewed in plan, the first semiconductor patterns and the second semiconductor patterns are arranged in a zigzag fashion.
